(19) United States
(12) Patent Application Publication
(10) Pub. No.: US 2025/0204046 A1
(43) Pub. Date: Jun. 19, 2025

(54) ELECTRONIC DEVICE

(71) Applicant: InnoLux Corporation, Miao-Li County (TW)

(72) Inventors: Yuan-Lin WU, Miao-Li County (TW); Kuan -Feng LEE, Miao-Li County (TW)

(73) Assignee: InnoLux Corporation, Miao-Li County (TW)

(21) Appl. No.: 18/955,871

(22) Filed: Nov. 21, 2024

(30) Foreign Application Priority Data
Dec. 19, 2023 (CN) 202311743647.9

(51) Int. Cl. H10D 86/40; H10D 86/60

(52) U.S. Cl. CPC H10D 86/443; H10D 86/471; H10D 86/60

(57) ABSTRACT

An electronic device having an active region and a peripheral region adjacent to the active region includes a substrate, a conductive layer disposed on the substrate, a first transistor disposed on the conductive layer and in the active region, a second transistor disposed on the substrate and in the peripheral region, and a conductive line electrically connected between the first transistor and the second transistor. In a top view of the electronic device, the conductive layer includes an outer surrounding portion in the peripheral region and between the first transistor and the second transistor, and the conductive line crosses the outer surrounding portion and is electrically insulated from the outer surrounding portion.

### BACKGROUND OF THE DISCLOSURE

### 1. Field of the Disclosure

The present disclosure relates to an electronic device, and more particularly to an electronic device capable of improving reliability of electronic units.

### 2. Description of the Prior Art

Active elements (such as transistors, but not limited thereto) in the electronic device may be damaged by polarization phenomena of the substrate, signals from the stylus, or other factors. For example, active elements may be damaged by electrostatic discharge, thereby affecting the reliability of the electronic device. Therefore, to improve the reliability of active elements in the electronic device is still an important issue in the present field.

### SUMMARY OF THE DISCLOSURE

The present disclosure aims at providing an electronic device capable of improving reliability of electronic units.

An electronic device having an active region and a peripheral region adjacent to the active region is provided by the present disclosure. The electronic device includes a substrate, a conductive layer disposed on the substrate, a first transistor disposed on the conductive layer and in the active region, a second transistor disposed on the substrate and in the peripheral region, and a conductive line electrically connected between the first transistor and the second transistor. In a top view of the electronic device, the conductive layer includes an outer surrounding portion in the peripheral region and between the first transistor and the second transistor, and the conductive line crosses the outer surrounding portion and is electrically insulated from the outer surrounding portion.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1A schematically illustrates a partial cross-sectional view of an electronic device according to a first embodiment of the present disclosure.

FIG. 1B schematically illustrates a partial enlarged cross-sectional view of the electronic device according to the first embodiment of the present disclosure.

FIG. 2 schematically illustrates a top view of the electronic device according to the first embodiment of the present disclosure.

FIG. 3 schematically illustrates an equivalent circuit diagram of a driving unit according to the first embodiment of the present disclosure.

FIG. 4 schematically illustrates a top view of an electronic device according to a second embodiment of the present disclosure.

FIG. 5 schematically illustrates a top view of an electronic device according to a third embodiment of the present disclosure.

FIG. 6 schematically illustrates a partial top view of an electronic device according to a fourth embodiment of the present disclosure.

FIG. 7 schematically illustrates a partial top view of an electronic device according to a fifth embodiment of the present disclosure.

FIG. 8 schematically illustrates a top view of an electronic device according to a sixth embodiment of the present disclosure.

FIG. 9 schematically illustrates a partial cross-sectional view of an electronic device according to a seventh embodiment of the present disclosure.

FIG. 10 schematically illustrates a cross-sectional view of an electronic device according to an eighth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other suitable electronic devices, but not limited thereto. The electronic device may be a foldable electronic device, a flexible electronic device or a stretchable electronic device. The display device may include a non-self-emissive display device or a self-emissive display device. The non-self-emissive display device for example includes a liquid crystal display device, but not limited thereto. The self-emissive display device for example includes a light emitting diode display device, but not limited thereto. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode or a photo diode. The light emitting diode may for example include an organic light emitting diode (OLED) or an inorganic light emitting diode. The inorganic light emitting diode may for example include a mini light emitting diode (mini LED), a micro light emitting diode (micro LED) or a quantum dot light emitting diode (QLED), but not limited thereto. It should be noted that the electronic device of the present disclosure may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The display device is taken as an example of the electronic device for describing the contents of the present disclosure in the following, but the present disclosure is not limited thereto.

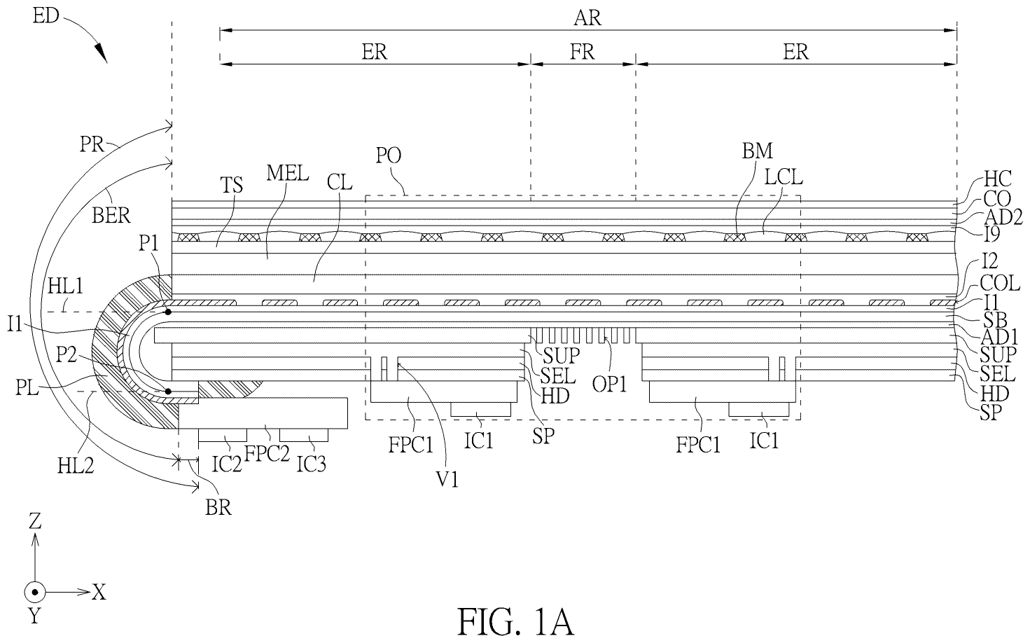

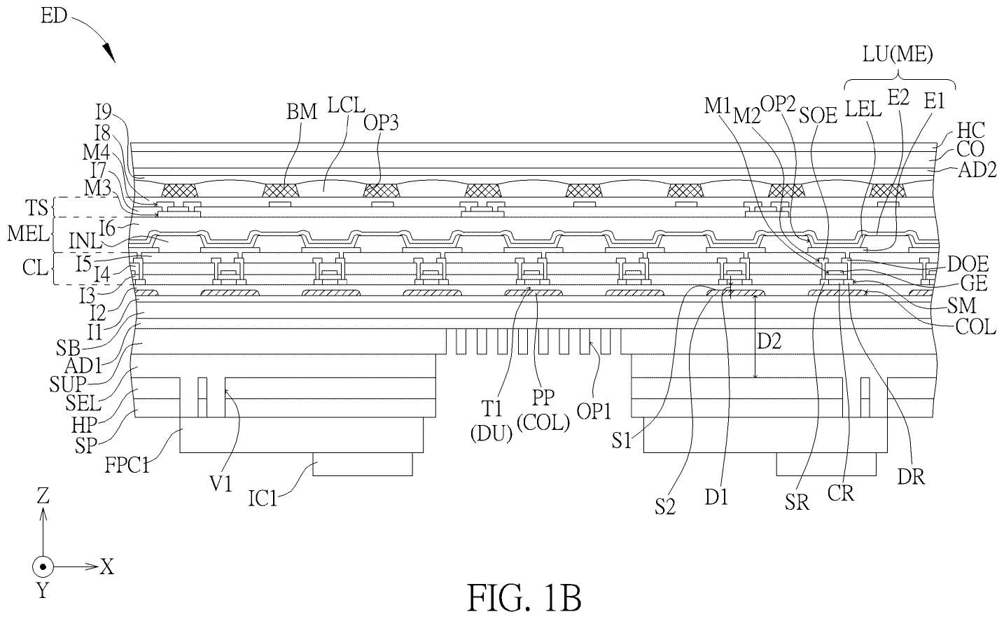

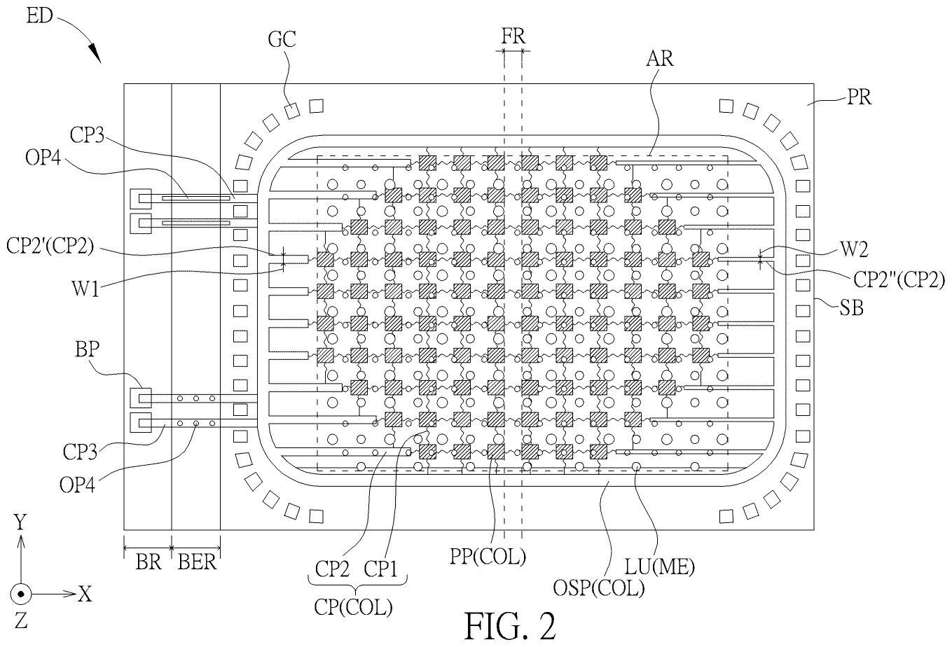

Referring to FIG. 1A, FIG. 1B and FIG. 2, FIG. 1A schematically illustrates a partial cross-sectional view of an electronic device according to a first embodiment of the present disclosure, FIG. 1B schematically illustrates a partial enlarged cross-sectional view of the electronic device according to the first embodiment of the present disclosure, and FIG. 2 schematically illustrates a top view of the electronic device according to the first embodiment of the present disclosure. As shown in FIG. 1A, the electronic device ED may include a substrate SB, a circuit layer CL disposed on the substrate SB and an electronic element layer MEL disposed on the circuit layer CL, but not limited thereto. The electronic element layer MEL may include electronic elements ME, as shown in FIG. 1B. Specifically, the circuit layer CL, the electronic element layer MEL and the touch structure TS are shown as a single layer in FIG. 1A, and the detailed structures thereof may refer to FIG. 1B. FIG. 1B for example shows an enlarged cross-sectional view of the portion PO shown in FIG. 1A. The type of electronic element ME may be determined according to the type or purpose of the electronic device ED. For example, the electronic device ED of the present embodiment may include a display device, and the electronic elements ME may include light emitting elements, but not limited thereto. In some embodiments, the electronic device ED may include a sensing device, and the electronic elements ME may include any suitable sensing element, such as optical sensing element or thermal sensing element. In some embodiments, the electronic elements ME may include electromagnetic wave transmitting/receiving elements, such as antenna elements, but not limited thereto.

The substrate SB may be used to support the elements and the layers disposed thereon. The substrate SB may include a rigid material or a flexible material. The rigid material for example includes glass, quartz, sapphire, ceramic, other suitable materials or combinations of the above-mentioned materials. The flexible material for example includes polyimide (PI), polycarbonate (PC), polyethylene terephthalate (PET), other suitable materials or combinations of the above-mentioned materials. At least a portion of the substrate SB may include the flexible material, such that the substrate SB may be a flexible substrate, but not limited thereto. It should be noted that the substrate SB may include a multi-layer structure in some embodiments, which is not limited to what is shown in FIG. 1A or FIG. 1B.

The circuit layer CL may include various kinds of wires, circuits or electronic units that can be applied to the electronic device ED. The electronic unit may include any suitable active element and/or passive element. The circuit layer CL may include any suitable structure formed by stacking conductive layer(s) and insulating layer(s), wherein the conductive layer(s) may be used for forming the wires, the circuits or the electronic units mentioned above. The stacking direction of the conductive layer(s) and the insulating layer(s) in the circuit layer CL may be parallel to the top view or the normal direction (that is, the direction Z, which will not be redundantly described in the following) of the electronic device ED. For example, as shown in FIG. 1B, the circuit layer CL may include driving circuits DU, wherein the driving circuits DU may be electrically connected to any suitable electronic element in the electronic device ED. For example, a driving circuit DU may be electrically connected to an electronic element ME. The driving circuit DU may include transistor(s), such as the transistor T1 shown in FIG. 1B. The transistor T1 may be a thin film transistor (TFT), but not limited thereto. Specifically, the circuit layer CL may include a semiconductor layer SM, a conductive layer M1 and a conductive layer M2, wherein the semiconductor layer SM may form the channel region CR, the source region SR and the drain region DR of the transistor T1, and the conductive layer M1 may form the gate electrode GE of the transistor T1. The channel region CR may be defined as a portion of the semiconductor layer SM overlapped with the gate electrode GE. The conductive layer M2 is located on the conductive layer M1 and may form the source electrode SOE and the drain electrode DOE respectively electrically connected to the source region SR and the drain region DR. The semiconductor layer SM may include a semiconductor material. The semiconductor material may include silicon or metal oxides, such as low temperature polysilicon (LTPS) semiconductor, amorphous silicon (a-Si) semiconductor, indium gallium zinc oxide (IGZO) semiconductor, low temperature polysilicon oxide (LTPO) or combinations of the above-mentioned materials, but not limited thereto. The conductive layer M1 and the conductive layer M2 may include any suitable conductive material, such as metal materials, but not limited thereto. The circuit layer CL may further include an insulating layer I3 disposed between the semiconductor layer SM and the conductive layer M1, an insulating layer I4 disposed between the conductive layer M1 and the conductive layer M2 and an insulating layer I5 disposed on the insulating layer I4. The insulating layer I3, the insulating layer I4 and the insulating layer I5 may include any suitable insulating material, such as organic insulating materials or inorganic insulating materials. In some embodiments, the insulating layer I3 may be the gate insulating layer of the transistor T1. It should be noted that the structure of the circuit layer CL shown in FIG. 1B is exemplary, and the present embodiment is not limited thereto.

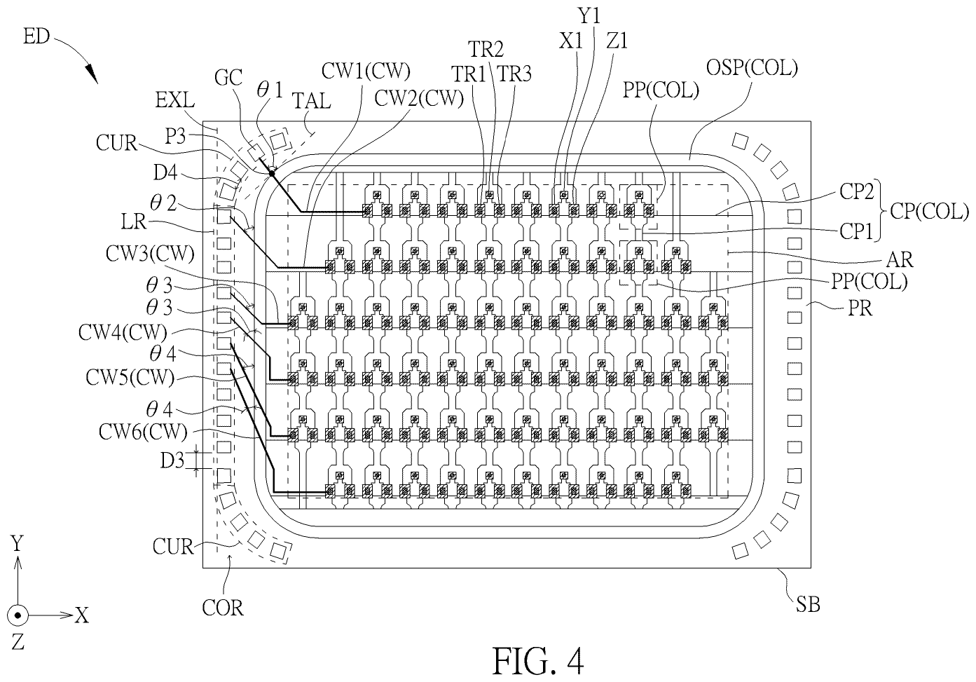

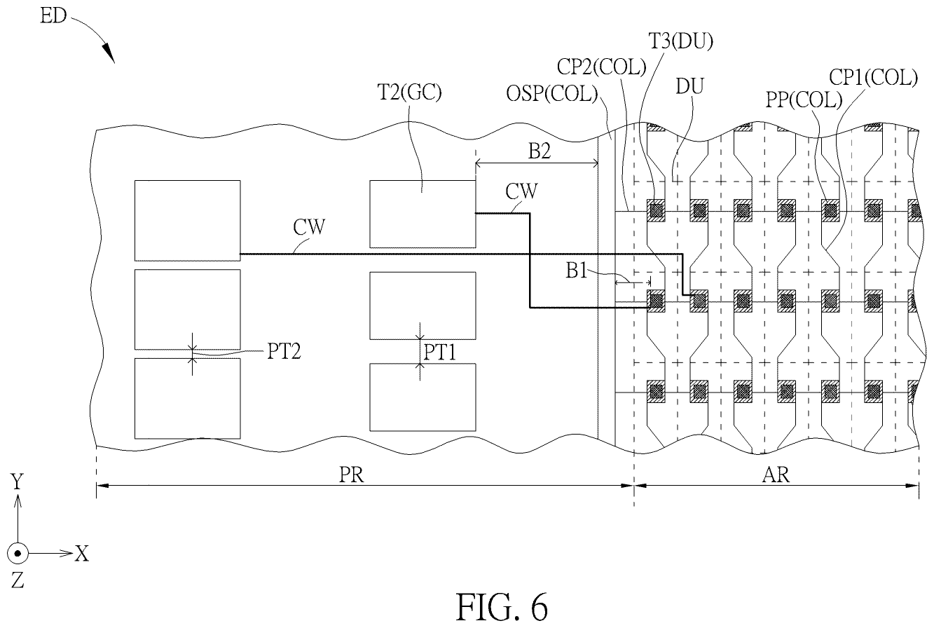

As shown in FIG. 2, the electronic device ED may include gate driving circuits GC disposed on the substrate SB. The gate driving circuit GC may include amplifier, signal line, shift register and/or other suitable elements, but not limited thereto. The gate driving circuit GC may include transistor(s) (not shown in FIG. 2, which can refer to the transistor T2 shown in FIG. 6). The structure of the gate driving circuit GC is exemplarily shown as a frame in FIG. 2. Specifically, the frame in FIG. 2 shows the disposition position of the gate driving circuit GC. That is, the transistors in the gate driving circuits GC may be disposed at intervals, but not limited thereto. In some embodiments, the frame shown in FIG. 2 may represent a group of transistors formed of the transistors in a gate driving circuit GC, and the groups of the transistors may be disposed at intervals. The transistor(s) in the gate driving circuit GC may be electrically connected to the transistor(s) in the driving circuit DU through a conductive line (not shown in FIG. 2, which can refer to the conductive line CW shown in FIG. 4 and FIG. 6). It should be noted that in order to simplify the figure, the gate driving circuit GC is not shown in FIG. 1A.

Referring to FIG. 1B, the electronic element layer MEL includes the electronic elements ME. The electronic elements ME of the present embodiment may include light emitting units LU, but not limited thereto. The light emitting units LU may include self-emissive elements or non-self-emissive elements. The self-emissive element may include a light emitting diode, but not limited thereto. The light emitting diode may include organic light emitting diode (OLED), quantum light-emitting diode (QLED or QDLED), inorganic light emitting diode, other suitable light emitting elements or combinations of the above-mentioned elements. The inorganic light emitting diode may for example include mini light emitting diode (mini LED) or micro light emitting diode (micro LED), but not limited thereto. The non-self-emissive element may for example include liquid crystal layer, but not limited thereto. The light emitting units LU of the present embodiment may include organic light emitting diodes, but not limited thereto. Specifically, the light emitting unit DU may include an electrode E1, an electrode E2 and a light emitting layer LEL disposed between the electrode E1 and the electrode E2. The electrode E1 may be disposed on the insulating layer I5 of the circuit layer CL, the light emitting layer LEL may be disposed on the electrode E1, and the electrode E2 may be disposed on the light emitting layer LEL. The electronic device ED may further include an insulating layer INL disposed on the insulating layer I5, wherein the insulating layer INL may partially cover the electrode E1 and may expose a portion of the electrode E1. The insulating layer INL may include a plurality of openings OP2, and the light emitting layer LEL may be disposed corresponding to the openings OP2, or the light emitting layer LEL may be disposed in the openings OP2 of the insulating layer INL. Specifically, the opening OP2 may expose the electrode E1, and the light emitting layer LEL may be disposed on the portion of the electrode E1 exposed by the opening OP2. The insulating layer INL may serve as the pixel defining layer (PDL). The electrode E2 may be a continuous layer conformally disposed on the light emitting layer LEL and the insulating layer INL, that is, the electrodes E2 of different light emitting units LU may be connected to each other, but not limited thereto. The electrode E1 may be electrically connected to the driving circuit DU (for example, the drain electrode DOE of the transistor in the driving circuit DU), thereby electrically connecting the light emitting unit LU to the driving circuit DU. The electronic device ED may further include an insulating layer I6 disposed on the electronic elements ME (or the light emitting units LU), wherein the insulating layer I6 may be disposed on the electrode E2. The insulating layer I6 may serve as the encapsulation layer for encapsulating the elements and the layers there below. In addition, the insulating layer I6 may provide a flat top surface to facilitate the disposition of other elements and layers on the insulating layer I6.

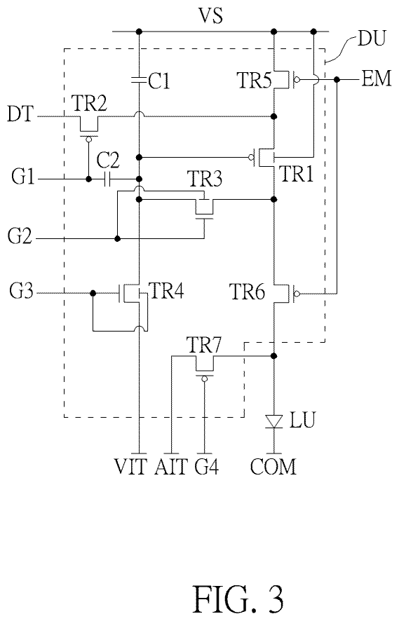

In the present embodiment, a driving circuit DU may include a plurality of transistors, and the transistor T1 shown in FIG. 1B may be one of the transistors in the driving circuit DU. In other words, FIG. 1B just exemplarily shows the driving circuit DU through the transistor T1. Referring to FIG. 3, FIG. 3 schematically illustrates an equivalent circuit diagram of a driving unit according to the first embodiment of the present disclosure. In the present embodiment, a driving circuit DU may include a transistor TR1, a transistor TR2, a transistor TR3, a transistor TR4, a transistor TR5, a transistor TR6 and a transistor TR7. In addition, the driving circuit DU may further include a capacitor C1 and a capacitor C2. The transistor T1 shown in FIG. 1B may be one of the transistor TR1, the transistor TR2, the transistor TR3, the transistor TR4, the transistor TR5, the transistor TR6 and the transistor TR7.

An end of the light emitting unit LU (for example, the electrode E1, but not limited thereto) may be electrically connected to the transistor TR6 and the transistor TR7. It should be noted that “the light emitting unit LU is electrically connected to the transistor TR6 and the transistor TR7” described herein may include the embodiment that the light emitting unit LU is electrically connected to the transistor TR6 and the transistor TR7 through other electronic elements, wherein these electronic elements may be formed of different layers or formed of the same layer. Another end of the light emitting unit LU (for example, the electrode E2, but not limited thereto) may be electrically connected to a common voltage COM. In other words, “the electrode E1 of the light emitting unit LU is electrically connected to the transistor in the driving circuit DU” mentioned above may for example represent that the electrode E1 is electrically connected to the transistor TR6 and the transistor TR7 in the driving circuit DU.

An end of the capacitor C1 may be electrically connected to the transistor TR1, and another end of the capacitor C1 may be electrically connected to a source voltage VS. The capacitor C1 may be used to maintain the voltage of the gate electrode of the transistor TR1 during a period when the first gate signal G1 is not received.

An end of the capacitor C2 may be electrically connected to the transistor TR3. Another end of the capacitor C2 may be electrically connected to the gate driving circuit GC (as shown in FIG. 2) and may receive the first gate signal G1. The capacitor C2 may be used to compensate for the voltage drop of the gate electrode of the transistor TR1.

The gate electrode of the transistor TR1 may be electrically connected to an end of the capacitor C1, the source electrode of the transistor TR1 may be electrically connected to the transistor TR2 and receive a data voltage DT, and the drain electrode of the transistor TR1 may be electrically connected to the transistor TR6. The transistor TR1 may serve as the driving transistor.

The gate electrode of the transistor TR2 may receive the first gate signal G1. Specifically, the gate electrode of the transistor TR2 may be electrically connected to the scan line (not shown) so as to receive the first gate signal G1. The source electrode of the transistor TR2 may receive the data voltage DT. Specifically, the source electrode of the transistor TR2 may be electrically connected to the data line (not shown) so as to receive the data voltage DT. The drain electrode of the transistor TR2 may be electrically connected to the source electrode of the transistor TR1, such that the data voltage DT may be provided to the source electrode of the transistor TR1 when the transistor TR2 is turned on. The transistor TR2 may serve as the switch transistor.

The transistor TR3 may be a dual gate transistor and include a gate electrode and a bottom gate electrode. The gate electrode and the bottom gate electrode of the transistor TR3 may be electrically connected to the gate driving circuit GC and receive a second gate signal G2. The source electrode of the transistor TR3 may be electrically connected to the drain electrode of the transistor TR1, and the drain electrode of the transistor TR3 may be electrically connected to the gate electrode of the transistor TR1. The transistor TR3 may serve as a compensation transistor to compensate the threshold voltage of the transistor TR1.

The transistor TR4 may be a dual gate transistor and include a gate electrode and a bottom gate electrode. The gate electrode and the bottom gate electrode of the transistor TR4 may be electrically connected to the gate driving circuit GC and receive a third gate signal G3. The source electrode of the transistor TR4 may be electrically connected to the gate electrode of the transistor TR1, and the drain electrode of the transistor TR4 may receive a gate initialization voltage VIT. The transistor TR3 may serve as a gate initialization transistor for initializing the gate electrode of the transistor TR1 to have the gate initialization voltage VIT.

The gate electrode of the transistor TR5 may receive an emitting management signal EM. The source electrode of the transistor TR5 may receive the source voltage VS. The drain electrode of the transistor TR5 may be electrically connected to the transistor TR1. When the transistor TR5 receives the emitting management signal EM and being turned on, the source voltage VS may be provided to the transistor TR1 through the transistor TR5.

The gate electrode of the transistor TR6 may receive the emitting management signal EM. The source electrode of the transistor TR6 may be electrically connected to the transistor TR1. The drain electrode of the transistor TR6 may be electrically connected to the light emitting unit LU. When the transistor TR6 receives the emitting management signal EM and being turned on, the transistor TR6 may provide a driving current to the light emitting unit LU.

The gate electrode of the transistor TR7 may receive a fourth gate signal G4. The source electrode of the transistor TR7 may be electrically connected to the light emitting unit LU. The drain electrode of the transistor TR7 may receive an anode initialization voltage AIT. When the transistor TR7 receives the fourth gate signal G4 and being turned on, the transistor TR7 may provide the anode initialization voltage AIT to the light emitting unit LU, such that the electrode E1 of the light emitting unit LU may be initialized to have the anode initialization voltage AIT. In other words, the transistor TR7 may serve as an anode initialization transistor.

It should be noted that the number, type and electrical connection design of the transistors included in the driving circuit DU mentioned above are exemplary, and the present disclosure is not limited thereto.

As shown in FIG. 2, the electronic device ED may include an active region AR and a peripheral region PR. The active region AR may be a region where the electronic elements ME and the driving circuits DU (labeled in FIG. 1B) electrically connected to the electronic elements ME are disposed in the electronic device ED. In other words, the active region AR may be a region where the electronic elements ME work or a region that can be operated by the user in the electronic device ED. In a top view of the electronic device ED, the active region AR may be defined as the smallest rectangle enclosed by the outer edges of the outermost electronic elements ME and the driving circuits DU, but not limited thereto. “The outermost driving circuits DU” mentioned above may be the outermost transistors in the driving circuits DU. In other words, the active region AR may be defined as the smallest rectangle enclosed by the outer edges of the outermost elements among the electronic elements ME and the transistors of the driving circuits DU. After the active region AR is defined, the remaining region in the electronic device ED except for the active region AR may be defined as the peripheral region PR. The electronic elements ME and the driving circuits DU (or the transistors in the driving circuits DU) are disposed in the active region AR, and the gate driving circuits GC (or the transistors in the gate driving circuits GC) are disposed in the peripheral region PR.

In some embodiments, the electronic device ED may further include a touch structure TS disposed on the electronic elements ME. The touch structure TS may include a structure formed by stacking conductive layer(s) and insulating layer(s), but not limited thereto. For example, as shown in FIG. 1B, the electronic device ED may further include a conductive layer M3 disposed on the insulating layer I6, an insulating layer I7 disposed on the conductive layer M3, a conductive layer M4 disposed on the insulating layer I7, and an insulating layer I8 disposed on the conductive layer M4. The conductive layer M4 may be electrically connected to the conductive layer M3 through the vias passing through the insulating layer I7. The conductive layer M3 and the conductive layer M4 may include any suitable conductive material, such as metals, but not limited thereto. In the present embodiment, in the top view of the electronic device, the patterns of the conductive layers (for example, the conductive layer M3 and the conductive layer M4) in the touch structure TS may not overlap the light emitting unit LU or not overlap the light emitting region of the light emitting layer LEL of the light emitting unit LU. It should be noted that the disposition position of the touch structure TS in the electronic device ED is not limited to what is shown in FIG. 1A and FIG. 1B. In addition, the structure of the touch structure TS shown in FIG. 1B is exemplary, and the present disclosure is not limited thereto. The touch structure TS may include a resistive touch structure, a capacitive touch structure, an infrared touch structure, an ultrasonic touch structure, other suitable touch structures or combinations of the above-mentioned touch structures.

In some embodiments, the electronic device ED may further include an optical layer LCL and a black matrix layer BM disposed on the light emitting units LU. The optical layer LCL may include the element or the layer that can provide any suitable optical function, according to the design of the electronic device ED. For example, the optical layer LCL may include a light converting layer including any suitable material capable of changing the wavelength or the color of the light passing through the light converting layer. For example, the optical layer LCL may include color filters that allows light of specific wavelengths to pass through, but not limited thereto. In some embodiments, the optical layer LCL may include quantum dots, fluorescent, phosphorescent, other suitable materials or combinations of the above-mentioned materials. In the present embodiment, the electronic device ED may include a plurality of optical layers LCL, wherein the optical layers LCL may convert the light into different wavelengths or colors. For example, the optical layers LCL may respectively convert the light into red light, green light and blue light which can by mixed into white light, but not limited thereto. The optical layers LCL may be disposed corresponding to the light emitting units LU. The black matrix layer BM may be disposed between two adjacent optical layers LCL. Specifically, the black matrix layer BM may include a plurality of openings OP3, and the optical layers LCL may be disposed corresponding to the openings OP3 of the black matrix layer BM. As shown in FIG. 1A and FIG. 1B, the electronic device ED may further include an insulating layer I9 disposed on the optical layers LCL and the black matrix layer BM. The insulating layer I9 may provide a flat top surface to facilitate the disposition of other elements and layers on the insulating layer I9.

In some embodiments, the electronic device ED may further include a cover layer CO disposed on the light emitting units LU. Specifically, the cover layer CO may be attached to the insulating layer I9 through an adhesive layer AD2. It should be noted that although the cover layer CO shown in FIG. 1A and FIG. 1B includes a single layer structure, the present disclosure is not limited thereto. In some embodiments, the cover layer CO may include a multi-layer structure, such as the multi-layer structure formed by stacking an inorganic layer, an organic layer and an inorganic layer.

In some embodiments, the electronic device ED may further include a hard coating layer HC disposed on the cover layer CO. For example, the hard coating layer HC may be disposed at a side of the cover layer CO opposite to the optical layers LCL. The hard coating layer HC may provide protection to the elements and the layers disposed there below.

In some embodiments, the electronic device ED may further include a supporting plate SUP disposed under the substrate SB and disposed at a side of the substrate SB opposite to the circuit layer CL. As shown in FIG. 1A, the supporting plate SUP may be attached to the substrate SB through an adhesive layer AD1, but not limited thereto. The supporting plate SUP may include any suitable flexible supporting material. In the present embodiment, the active region AR of the electronic device ED may include a foldable sub region FR, wherein the portion of the electronic device ED in the foldable sub region FR may be folded, bent, rolled or deformed in other suitable ways. The portion of the electronic device ED in the foldable sub region FR may not be fixed or may be fixed when the electronic device ED is being used. In the present embodiment, the portion of the supporting plate SUP corresponding to the foldable sub region FR (shown in FIG. 1A and FIG. 2) may include at least one opening OP1. The opening OP1 may be formed by partially removing the portion of the supporting plate SUP corresponding to the foldable sub region FR. The opening OP1 may penetrate through the supporting plate SUP and expose the adhesive layer AD1, but not limited thereto. In some embodiments, the opening OP1 may not penetrate through the supporting plate SUP. Therefore, the flexibility of the supporting plate SUP may be improved. In some embodiments, the active region AR may include a plurality of foldable sub regions FR, which is not limited to what is shown in FIG. 1A. In the present embodiment, the remaining region in the active region AR except for the foldable sub region FR may be defined as the flat sub region ER. Specifically, the portion of the electronic device ED in the flat sub region ER may not be folded or deformed in other ways. In addition, the portion of the electronic device ED in the flat sub region ER may be fixed when the electronic device ED is being used.

In some embodiments, the electronic device ED may further include a sensing layer SEL, a heat dissipation layer HD and a supporting layer SP disposed under the substrate SB. As shown in FIG. 1A, the sensing layer SEL may be disposed at a side of the supporting plate SUP opposite to the substrate SB (or the back side of the substrate SB), the heat dissipation layer HD may be disposed at a side of the sensing layer SEL opposite to the substrate SB, and the supporting layer SP may be disposed at a side of the heat dissipation layer HD opposite to the sensing layer SEL. In other words, the heat dissipation layer HD is disposed between the sensing layer SEL and the supporting layer SP. The sensing layer SEL may include any suitable sensing element, such as touch sensing element, biological sensing element, distance sensing element, electromagnetic wave sensing element (such as an antenna), other suitable sensing elements or combinations of the above-mentioned elements. In some embodiments, the sensing layer SEL may include any suitable element that can sense finger, stylus or other suitable external objects. The sensing layer SEL may be electrically connected to a printed circuit board FPC1 through the via V1 passing through the heat dissipation layer HD and the supporting layer SP. The printed circuit board FPC1 for example includes a flexible printed circuit board (FPCB), but not limited thereto. The electronic device ED may further include an electronic unit IC1 electrically connected to the printed circuit board FPC1. The electronic unit IC1 may be used to drive/control the sensing layer SEL. The electronic unit IC1 for example includes a chip, other suitable electronic units, or combinations of the above-mentioned elements. The heat dissipation layer HD may be used to dissipate the heat generated by the elements such as the sensing layer SEL, the printed circuit board FPC1, the electronic unit IC1, and the like. The heat dissipation layer HD may include any suitable high thermal conductivity material, such as copper, but not limited thereto. The supporting layer SP may provide the supporting effect to the heat dissipation layer HD, the sensing layer SEL, the printed circuit board FPC1 and the electronic unit IC1. In the present embodiment, the sensing layer SEL may be disposed to be misaligned with the foldable sub region FR in the active region AR. For example, the electronic device ED may include two sensing layers SEL respectively be disposed at two sides of the foldable sub region FR and corresponding to the flat sub regions ER, but not limited thereto. In such condition, the electronic device ED may include two heat dissipation layers HD, two supporting layers SP, two printed circuit boards FPC1 and two electronic units IC1 which are respectively disposed corresponding to the two sensing layers SEL. Therefore, the damage to the sensing layers SEL and the electronic units IC1 may be reduced when the electronic device ED is flexed.

The electronic device ED may further include a printed circuit board FPC2 disposed on the substrate SB and an electronic unit IC2 and an electronic unit IC3 disposed on the printed circuit board FPC2. The printed circuit board FPC2 may for example include a flexible printed circuit board, but not limited thereto. The driving circuits DU and the gate driving circuits GC may be electrically connected to the printed circuit board FPC2, thereby being electrically connected to the electronic unit IC2. Therefore, the driving circuits DU and the gate driving circuits GC may be controlled through the electronic unit IC2. The electronic unit IC3 may be used to drive/control the touch structure TS, but not limited thereto. In some embodiments, the electronic unit IC3 may be used to drive/control other electronic elements in the electronic device ED. The electronic unit IC2 and the electronic unit IC3 for example include chips, other suitable electronic units or combinations of the above-mentioned elements. In the present embodiment, the portion of the substrate SB on which the printed circuit board FPC2, the electronic unit IC2 and the electronic unit IC3 are disposed may be bent backward, such that the printed circuit board FPC2, the electronic unit IC2 and the electronic unit IC3 may be disposed at the same side (that is, the backside of the substrate SB) as he sensing layer SEL. Specifically, the peripheral region PR of the electronic device ED may further include a bending sub region BER and a bonding sub region BR. The bending sub region BER may be connected between the bonding sub region BR and the active region AR, but not limited thereto. The bending sub region BER may be defined as the region to which the portion of the substrate SB that is bent and fixed would correspond when the electronic device ED is being used. Specifically, the substrate SB of the electronic device ED may start to deviate from a horizontal extending line HL1 parallel to the extending direction of the outer surface of the substrate SB (for example, the direction X) at a point P1, and the substrate SB may start to deviate from another horizontal extending line HL2 parallel to the extending direction of the outer surface of the substrate SB at a point P2, and the bending sub region BER may be defined as the region corresponding to the portion of the substrate SB between the point P1 and the point P2. The bonding sub region BR may be defined as the region in the substrate SB corresponding to the above-mentioned elements such as the printed circuit board FPC2, the electronic unit IC2, the electronic unit IC3 and the like. That is, the gate driving circuits GC and the driving circuits DU may be electrically connected to the printed circuit board FPC2, the electronic unit IC2 and the electronic unit IC3 at the bonding sub region BR. The electronic device ED may further include a protecting layer PL, wherein the protecting layer PL may be disposed corresponding to the peripheral region PR. Specifically, the protecting layer PL may cover the portion of the electronic device ED in the peripheral region PR, thereby providing the protecting effect for the electronic device ED. The protecting layer PL may include any suitable protecting material, such as a waterproof layer, but not limited thereto.

According to the present disclosure, the electronic device ED may include a conductive layer COL disposed on the substrate SB. Specifically, in the top view of the electronic device ED, the conductive layer COL is disposed between the substrate SB and the driving circuits DU, or the conductive layer COL is disposed between the substrate SB and the transistors in the driving circuits DU. For example, as shown in FIG. 1A and FIG. 1B, the electronic device ED may include an insulating layer I1 disposed on the substrate SB, the conductive layer COL disposed on the insulating layer I1, and an insulating layer I2 disposed on the conductive layer COL, but not limited thereto. The insulating layer I1 may be disposed between the substrate SB and the conductive layer COL. The insulating layer I2 may be disposed between the conductive layer COL and the driving circuits DU (for example, the semiconductor layers SM of the transistors in the driving circuits DU). It should be noted that other elements and/or layers may be included between the substrate SB and the circuit layer CL.

The conductive layer COL may be a patterned layer. Specifically, as shown in FIG. 2, the conductive layer COL may include a plurality of pattern portions PP, a plurality of connecting portions CP and an outer surrounding portion OSP, but not limited thereto. The pattern portion PP may include any suitable shape, such as rectangle, but not limited thereto. In the top view of the electronic device, the pattern portions PP may be arranged in an array, but not limited thereto. In the top view of the electronic device, the outer surrounding portion OSP may surround the pattern portions PP of the conductive layer COL. For example, as shown in FIG. 2, the outer surrounding portion OSP of the present embodiment may have a ring structure and surround the pattern portions PP, but not limited thereto. It should be noted that “the outer surrounding portion OSP surrounds the pattern portions PP” mentioned above may include the condition that the outer surrounding portion OSP is disposed along at least one side of the pattern portions PP, that is, the outer surrounding portion OSP is not limited to include a closed shape or a ring shape. In some embodiments, the outer surrounding portion OSP may include two portions which are separated from each other and respectively disposed at two opposite sides of the pattern portions PP. The connecting portions CP may be connected between two adjacent pattern portions PP and between the pattern portion PP and the outer surrounding portion OSP. For example, the connecting portions CP may include a connecting portion CP1 connecting two adjacent pattern portions PP and a connecting portion CP2 connecting the pattern portion PP and the outer surrounding portion OSP, but not limited thereto. The connecting portion CP may be strip-shaped or similar to a strip, but not limited thereto. For example, the connecting portion CP1 may have a curved strip structure, and the connecting portion CP2 may have a linear structure, but not limited thereto. The shapes of the connecting portion CP1 and the connecting portion CP2 may be the same or different, it is not limited in the present disclosure. It should be noted that the some of the connecting portions CP (not labeled in figure) may connect the pattern portions PP and the connecting portions CP2, but not limited thereto. The pattern of the conductive layer COL shown in FIG. 2 is exemplary, and the present embodiment is not limited thereto.

In the top view of the electronic device ED, the pattern portions PP of the conductive layer COL may overlap the driving circuits DU or overlap the transistors in the driving circuits. Specifically, a pattern portion PP may overlap the transistor(s) in a driving circuit DU, but not limited thereto. In the present embodiment, “a pattern portion PP overlaps the transistor(s) in a driving circuit DU” mentioned above may indicate that the pattern portion PP at least overlaps the transistor with the greatest size among the transistors in the driving circuit DU. For example, in the present embodiment, the driving circuit DU may include seven transistors (refer to the structure shown in FIG. 3 and related description above), wherein the transistor TR1 may be the one having the greatest size among the seven transistors. In such condition, a pattern portion PP may at least overlap the transistor TR1 in a driving circuit DU. “The size of the transistor” mentioned above may be the length or the width of the transistor. In other words, the transistor TR1 may be the one having the greatest length or the greatest width among the seven transistors. In some embodiments, a pattern portion PP may overlap a plurality of transistors in a driving unit DU, wherein the plurality of transistors may include the transistor TR1. FIG. 1B shows the structure that the pattern portions PP of the conductive layer COL overlap the transistors of the driving circuit DU. In such condition, the transistor T1 shown in FIG. 1B may be the transistor TR1 shown in FIG. 3. It should be noted that “the pattern portion PP overlaps the transistor in the driving circuit DU” mentioned above may include the embodiment that the pattern portion PP at least partially overlaps the channel region CR of the semiconductor layer SM of the transistor in the driving circuit DU. In short, a pattern portion PP may at least partially overlap the channel region CR of the semiconductor layer SM of a transistor in the driving circuit DU. As mentioned above, the driving circuits DU may be disposed in the active region AR. Therefore, the pattern portions PP of the conductive layer COL overlapped with the driving circuits DU are disposed in the active region AR. As shown in FIG. 2, the range of the active region AR may cover the disposition range of the pattern portions PP. In such condition, the active region AR may be defined as the smallest rectangle enclosed by the outermost elements among the electronic elements ME and the pattern portions PP in some embodiments, which is shown in FIG. 2. In summary, the electronic device ED includes a plurality of first transistors disposed on the conductive layer COL and in the active region AR, wherein the plurality of pattern portions PP of the conductive layer COL respectively overlap the first transistors. The first transistors described herein is the transistors in the driving circuits DU, which are disposed in the active region AR and configured to drive the electronic units (that is, the electronic elements ME) in the active region AR. For example, the first transistor may be the transistor T1 shown in FIG. 1B.

According to the present embodiment, the outer surrounding portion OSP is disposed in the peripheral region PR and between the driving circuits DU and the gate driving circuits GC. Specifically, the outer surrounding portion OSP is disposed between the transistors in the driving circuits DU and the transistors in the gate driving circuits GC. In such condition, the outer surrounding portion OSP may surround the electronic elements ME. The connecting portions CP may be disposed in the active region AR and the peripheral region PR. Specifically, the connecting portions CP1 connecting adjacent pattern portions PP may be located in the active region AR, and the connecting portions CP2 connecting the pattern portions PP and the outer surrounding portion OSP may extend from the active region AR to the peripheral region PR.

By disposing the conductive layer COL between the substrate SB and the transistors in the driving circuits DU and making the conductive layer COL include the above-mentioned pattern design, the possibility that the transistors in the driving circuits DU are damaged by electrostatic discharge caused by the use of the sensing layer SEL or the polarization phenomenon of the substrate SB may be reduced, thereby improving the reliability of the electronic device ED.

In the present embodiment, as shown in FIG. 1B, in a normal direction (that is, the direction Z) of the electronic device ED, a distance D1 may be included between the conductive layer COL and the transistor in the driving circuit DU, and a distance D2 may be included between the conductive layer COL and the sensing layer SEL, wherein the distance D1 may be less than the distance D2. “The distance D1 between the conductive layer COL and the transistor in the driving circuit DU” mentioned above may be defined as the minimum distance (or may be the vertical distance) between the conductive layer COL and the channel region CR of the semiconductor layer SM of the transistor in the driving circuit DU, and “the distance D2 between the conductive layer COL and the sensing layer SEL” may be defined as the minimum distance (or may be the vertical distance) between the conductive layer COL and the sensing layer SEL. For example, the distance D1 may be the vertical distance from the top surface S1 of the conductive layer COL to the bottom surface (not labeled) of the semiconductor layer SM of the transistor in the driving circuit DU, and the distance D2 may be the vertical distance from the bottom surface S2 of the conductive layer COL to the top surface (not labeled) of the sensing layer SEL, but not limited thereto. In the present embodiment, a ratio of the distance D2 to the distance D1 may be greater than or equal to 20 and less than or equal to 1000 (that is, 20≤D2/D1≤1000), but not limited thereto. In some embodiments, the ratio of the distance D2 to the distance D1 may be greater than or equal to 30 and less than or equal to 900 (that is, 30≤D2/D1≤900). In some embodiments, the ratio of the distance D2 to the distance D1 may be greater than or equal to 40 and less than or equal to 800 (that is, 40≤D2/D1≤800). The distance D1 may range from 0.5 micrometer (μm) to 5 μm (that is, 0.5 μm≤D1≤5 μm), but not limited thereto. In some embodiments, the distance D1 may range from 1 μm to 4 μm (that is, 1 μm≤D1≤4 μm). In some embodiments, the distance D1 may range from 1.5 μm to 3 μm (that is, 1.5 μm≤D1≤3 μm). The distance D2 may range from 100 μm to 500 μm (that is, 100 μm≤D2≤500 μm), but not limited thereto. In some embodiments, the distance D2 may range from 150 μm to 450 μm (that is, 150 μm≤D2≤450 μm). In some embodiments, the distance D2 may range from 200 μm to 400 μm (that is, 200 μm≤D2≤400 μm). In summary, in the top view of the electronic device ED, the distance D1 may be included between the conductive layer COL and a first transistor, the distance D2 may be included between the conductive layer COL and the sensing layer SEL, and the distance D1 is less than the distance D2, wherein the first transistor is the transistor in the driving circuit DU which is disposed in the active region AR and configured to drive an electronic unit (that is, the electronic element ME) in the active region AR. Through the above-mentioned design, the possibility that the semiconductor layer SM of the transistor is damaged by electrostatic discharge may be reduced. The above-mentioned design may be applied to the embodiments and variant embodiments of the present disclosure.

In the present embodiment, the cross-sectional structure of the conductive layer COL may include a rounded corner structure or other suitable non-sharp corner structures. In other words, the cross-sectional structure of the conductive layer COL may include a curved edge. For example, in the cross-sectional view (such as FIG. 1A and FIG. 1B) of the electronic device ED, the shape of the cross-sectional view of the patter portion PP of the conductive layer COL may include a curved edge, but not limited thereto. Through the above-mentioned design, the possibility of electrostatic discharge may be reduced. It should be noted that the cross-sectional structures of the connecting portion CP and the outer surrounding portion OSP of the conductive layer COL may also include the rounded corner structure or other suitable non-sharp corner structures. The pattern design of the cross-sectional structure of the conductive layer COL described herein may be applied to the embodiments and variant embodiments of the present disclosure.

In the present embodiment, the connecting portions CP2 disposed at different positions for connecting the pattern portions PP and the outer surrounding portion OSP may have different widths. Specifically, as shown in FIG. 2, the connecting portion CP2 (that is, the connecting portion CP2′) connecting the pattern portion PP and a portion of the outer surrounding portion OSP adjacent to the bonding sub region BR (that is, a side of the outer surrounding portion OSP adjacent to the bonding sub region BR) may have a width W1, and the connecting portion CP2 (that is, the connecting portion CP2″) connecting the pattern portion PP and another portion of the outer surrounding portion OSP opposite to the portion of the outer surrounding portion OSP adjacent to the bonding sub region BR (that is, another side of the outer surrounding portion OSP opposite to the side of the outer surrounding portion OSP adjacent to the bonding sub region BR, or the side of the outer surrounding portion OSP furthest away from the bonding sub region BR) may have a width W2, wherein the width W1 may be different from the width W2. In the present embodiment, a portion of the outer surrounding portion OSP adjacent to the bonding sub region BR and another portion of the outer surrounding portion OSP opposite to the portion of the outer surrounding portion OSP may be the two portions of the outer surrounding portion OSP respectively be corresponding to two opposite sides of the active region AR. The definition of the bonding sub region BR may refer to the contents above, and will not be redundantly described. According to the present embodiment, the width (that is, the width W1) of the connecting portion CP connected to a portion of the outer surrounding portion OSP adjacent to the bonding sub region BR may be greater than the width (that is, the width W2) of the connecting portion CP connected to another portion of the outer surrounding portion OSP opposite to the portion of the outer surrounding portion OSP (that is, W1>W2). “The width of a connecting portion CP2” mentioned above may indicate the size of the connecting portion CP2 in a direction perpendicular to the extending direction of the connecting portion CP2. For example, as shown in FIG. 2, the connecting portion CP2′ may extend along the direction X, and the width W1 of the connecting portion CP2′ may be the size of the connecting portion CP2′ in the direction Y which is perpendicular to the direction X. Through the above-mentioned width design of the connecting portion CP2, the anti-electrostatic discharge effect of the conductive layer COL may be improved, thereby improving the reliability of the electronic device ED. In summary, in the present embodiment, the conductive layer COL includes a first connecting portion (that is, the connecting portion CP2′ in FIG. 2) and a second connecting portion (that is, the connecting portion CP2″ in FIG. 2), the first connecting portion is connected to a portion of the outer surrounding portion OSP adjacent to the bonding sub region BR, the second connecting portion is connected to another portion of the outer surrounding portion OSP opposite to the first connecting portion, and the width of the first connecting portion (that is, the width W1) may be greater than the width of the second connecting portion (that is, the width W2). In some embodiments, the width of the connecting portion CP2 (that is, the connecting portion CP2′) connected to a portion of the outer surrounding portion OSP adjacent to the bonding sub region BR may be greater than the widths of other connecting portions CP2 connected to the outer surrounding portion OSP. The width design of the connecting portion CP2 mentioned in the present embodiment may be applied to the embodiments and variant embodiments of the present disclosure.

According to the present embodiment, as shown in FIG. 2, the conductive layer COL may further include connecting portions CP3, wherein the connecting portions CP3 are connected to a portion of the outer surrounding portion OSP adjacent to the bonding sub region BR. Specifically, the connecting portions CP3 of the conductive layer COL may be disposed in the peripheral region PR and extend from the outer surrounding portion OSP toward the bonding sub region BR, wherein the connecting portions CP3 may pass through the bending sub region BER and extend to the bonding sub region BR, thereby being electrically connected to the bonding pads BP disposed in the bonding sub region BR. As shown in FIG. 2, the conductive layer COL may include a plurality of connecting portions CP3, and each of the connecting portions CP3 may be electrically connected to a bonding pad BP, but not limited thereto. The connecting portions CP3 of the conductive layer COL may extend in the bending sub region BER. FIG. 1A exemplarily shows the structure that the conductive layer COL extends in the bending sub region BER. That is, the portion of the conductive layer COL extending in the bending sub region BER may be the connecting portions CP3 (not labeled in FIG. 1A), but not limited thereto. The bonding pads BP may be electrically connected to any suitable electronic element in the electronic device ED, such as the electronic unit IC2 mentioned above, but not limited thereto. Therefore, the conductive layer COL may be electrically connected to the electronic unit IC2 through the connecting portions CP3. Through the above-mentioned design, the electrical signal may be transmitted to the conductive layer COL through the electronic unit IC2. In other words, the connecting portions CP3 of the conductive layer COL may be configured to transit a signal from the electronic unit IC2. For example, the electronic unit IC2 may transmit a common voltage to the conductive layer COL through the connecting portions CP3, but not limited thereto. Therefore, the instability of the conductive layer COL caused by floating may be reduced, thereby improving the reliability of the conductive layer COL. It should be noted that the conductive layer COL may not include the connecting portion CP3 in some embodiments, and the conductive layer COL may not be electrically connected to other electronic element.

As shown in FIG. 2, in the present embodiment, a portion of the connecting portion CP3 overlapped with the bending sub region BER may include at least one opening OP4, but not limited thereto. In some embodiments, a connecting portion CP3 may include an opening OP4, wherein the opening OP4 may include a strip-shaped structure and overlap the bending sub region BER, which is shown in the upper part of FIG. 2. In some embodiments, a connecting portion CP3 may include a plurality of openings OP4, wherein these openings OP4 may include circular structures and be disposed corresponding to the bending sub region BER, which is shown in the lower part of FIG. 2. It should be noted that the structure of the opening OP4 is not limited to what is shown in FIG. 2. The above-mentioned design may reduce the possibility of breakage of the connecting portion CP3, thereby improving the flexibility of the connecting portion CP3. The structural feature of the connecting portion CP3 described herein may be applied to the embodiments and variant embodiments of the present disclosure.

It should be noted that the structure of the electronic device ED of the present embodiment is not limited to what is shown in the figures mentioned above, and the electronic device ED may further include other suitable elements or layers. Other embodiments of the present disclosure will be described in the following. In order to simplify the description, the same elements or layers in the following embodiments would be labeled with the same symbol, and the features thereof will not be redundantly described. The differences between the embodiments will be detailed in the following. It should be noted that the features described in each of the embodiments may be applied to each other and are not limited to the structure in an embodiment.

Referring to FIG. 4, FIG. 4 schematically illustrates a top view of an electronic device according to a second embodiment of the present disclosure. In order to simplify the figure, the bending sub region BER and the bonding sub region BR of the electronic device ED are not shown in FIG. 4, and the structural features thereof may refer to the contents mentioned above. In addition, although it is not shown in FIG. 4, the active region AR of the electronic device ED may include the foldable sub region FR. According to the present embodiment, a pattern portion PP of the conductive layer COL may overlap a plurality of transistors in a driving circuit DU. Specifically, as shown in FIG. 4, the pattern portion PP of the conductive layer COL of the present embodiment may include a pattern sub portion X1, a pattern sub portion Y1 and a pattern sub portion Z1 which are connected to each other, wherein the pattern sub portion X1, the pattern sub portion Y1 and the pattern sub portion Z1 may respectively overlap a transistor in a driving circuit DU. In other words, a pattern portion PP may overlap three transistors in a driving circuit DU in the present embodiment, but not limited thereto. The three transistors that the pattern sub portion X1, the pattern sub portion Y1 and the pattern sub portion Z1 are overlapped with may include the transistor with the greatest size in the driving circuit DU, such as the transistor TRI mentioned above. For example, as shown in FIG. 4, the pattern sub portion X1, the pattern sub portion Y1 and the pattern sub portion Z1 in a pattern portion PP may respectively overlap the transistor TR1, the transistor TR2 and the transistor TR3, but not limited thereto. In some embodiments, the pattern sub portion Y1 and the pattern sub portion Z1 may respectively overlap any two of the transistors (that is, the above-mentioned transistor TR2, transistor TR3, transistor TR4, transistor TR5, transistor TR6 and transistor TR7) in the driving circuit DU except for the transistor TR1. In some embodiments, the transistor TR1 may overlap the pattern sub portion Y1 or the pattern sub portion Z1. In some embodiments, two of the pattern sub portion X1, the pattern sub portion Y1 and the pattern sub portion Z1 may respectively overlap the switch element (or the switch transistor, such as the transistor TR2) and the driving element (or the driving transistor, such as the transistor TR1). The material of the semiconductor layer of the switch transistor (for example, the transistor TR2) may include metal oxides, such as indium gallium zinc oxide (IGZO), but not limited thereto. The material of the semiconductor layer of the driving transistor (for example, the transistor TR1) may for example include low-temperature polycrystalline silicon (LTPS), but not limited thereto. As mentioned above, “the pattern portion PP overlaps a transistor” described in the present disclosure may indicate that the pattern portion PP at least partially overlaps the channel region CR of the semiconductor layer SM of the transistor. Therefore, the transistor TR1, the transistor TR2 and the transistor TR3 shown in FIG. 4 may for example represent the channel regions CR of the semiconductor layers SM of the transistor TR1, the transistor TR2 and the transistor TR3, respectively, but not limited thereto. It should be noted that the pattern of the pattern portion PP shown in FIG. 4 is exemplary, and the present embodiment is not limited thereto. In some embodiments, the pattern sub portion X1, the pattern sub portion Y1 and the pattern sub portion Z1 may be arranged or connected in other ways to form the pattern portion PP with any suitable pattern. In some embodiments, the pattern portion PP of the conductive layer COL may include any suitable pattern and may overlap two, four or more transistors in the driving circuit DU. The pattern design of the pattern portion PP of the present embodiment may be applied to the embodiments and variant embodiments of the present disclosure.

As mentioned above, in the present disclosure, the transistors in the driving circuits DU may be electrically connected to the transistors in the gate driving circuits GC. Specifically, as shown in FIG. 4, the electronic device ED may include a plurality of conductive lines CW, wherein one of the conductive lines CW may be electrically connected between a transistor in the driving circuit DU and a transistor in the gate driving circuit GC. It should be noted that FIG. 4 just exemplarily shows the feature that the conductive line CW is electrically connected between the transistor in the driving circuit DU and the transistor in the gate driving circuit GC through the structure in which the conductive line CW is electrically connected to the transistor TR1, and the conductive line CW may be electrically connected any suitable transistor in the driving circuit DU, based on the design of the driving circuit DU. In addition, FIG. 4 does not show all of the conductive lines CW. Furthermore, the position of the transistor to which the conductive line CW is electrically connected is exemplary, and the present embodiment is not limited thereto. According to the present embodiment, in the top view of the electronic device ED, the conductive line CW may extend between the driving circuits DU and the gate driving circuits GC and crosses the outer surrounding portion OSP located between the driving circuits DU and the gate driving circuits GC. In other words, in the top view of the electronic device ED, the conductive line CW may overlap the outer surrounding portion OSP, or the conductive line CW may intersect with the outer surrounding portion OSP. In addition, according to the present disclosure, the conductive line CW may not be electrically connected to the outer surrounding portion OSP of the conductive layer COL. Specifically, the conductive line CW and the outer surrounding portion OSP may be disposed in different layers, or at least one insulating layer (for example, the insulating layer I2, but not limited thereto) may exist between the conductive line CW and the outer surrounding portion OSP, such that the conductive line CW may be electrically insulated from the outer surrounding portion OSP. In summary, the electronic device ED of the present disclosure may include a conductive layer COL disposed on the substrate SB, a first transistor disposed on the conductive layer COL and located in the active region AR, a second transistor disposed on the substrate SB and located in the peripheral region PR, and a conductive line CW electrically connected between the first transistor and the second transistor, wherein in the top view of the electronic device ED, the conductive line CW crosses the outer surrounding portion OSP located in the peripheral region PR and between the first transistor and the second transistor, and the conductive line CW is electrically insulated from the outer surrounding: portion OSP. The first transistor is a transistor included in the driving circuit DU, which is configured to drive the electronic unit (that is, the electronic element ME) in the active region AR, and the second transistor is a transistor included in the gate driving circuit GC, wherein the transistor in the gate driving circuit GC may be electrically connected to the first transistor in the driving circuit DU.

The conductive line CW may crosses the outer surrounding portion OSP, and an included angel may be included between the conductive line CW and the outer surrounding portion OSP. According to the present embodiment, in the top view of the electronic device ED, an acute angle between the conductive line CW and the outer surrounding portion OSP may be greater than 20 degrees. “The acute angle between the conductive line CW and the outer surrounding portion OSP” mentioned above may be defined as the acute included angle between the conductive line CW and the outer edge of the outer surrounding portion OSP, but not limited thereto. Specifically, as shown in FIG. 4, an acute angle θ1 may be included between a conductive line CW1 connecting a transistor in a driving circuit DU and a transistor in a gate driving circuit GC and the outer edge of the outer surrounding portion OSP, and an acute angle θ2 may be included between a conductive line CW2 connecting another transistor in a driving circuit DU and another transistor in a gate driving circuit GC and the outer edge of the outer surrounding portion OSP, wherein the acute angle θ1 and the acute angle θ2 may be greater than 20 degrees (that is, θ1, θ2>20°), but not limited thereto. In some embodiments, the acute angle θ1 and the acute angle θ2 may be greater than 25 degrees (that is, θ1, θ2>25°). In some embodiments, the acute angle θ1 and the acute angle θ2 may be greater than 30 degrees (that is, θ1, θ2>30°). It should be noted that in some embodiments, when a conductive line CW (such as the conductive line CW1) intersects with the portion of the outer surrounding portion OSP with a curved edge, the acute angle (such as the acute angle θ1) between the conductive line CW and the outer surrounding portion OSP may be defined as the acute included angle between a tangent line (such as the tangent line TAL) passing through the intersection point (such as the point P3) of the conductive line CW and the outer edge of the outer surrounding portion OSP and the conductive line CW, but not limited thereto. In addition, FIG. 4 just exemplarily shows the feature that the acute angle θ1 and the acute angle θ2 are greater than 20 degrees, but the present embodiment is not limited thereto. Other acute angles may respectively be included between other conductive lines CW in the electronic device ED and the outer surrounding portion OSP, and these acute angles may be greater than 20 degrees.

In some embodiments, the acute angles between different conductive lines CW and the outer surrounding portion OSP may be different from each other. Specifically, the electronic device ED may include a first transistor and another first transistor (the first transistor is the transistor in the driving circuits DU) disposed in the active region AR, a second transistor and another second transistor (the second transistor is the transistor in the gate driving circuit GC) disposed in the peripheral region PR, a conductive line CW electrically connected between the first transistor and the second transistor, and another conductive line CW electrically connected between the another first transistor and the another second transistor, wherein an acute angle between the conductive line CW and the outer surrounding portion OSP may be different from an acute angle between the another conductive line CW and the outer surrounding portion OSP. For example, as shown in FIG. 4, the acute angle θ1 between the conductive line CW1 and the outer surrounding portion OSP may be different from the acute angle θ2 between the conductive line CW2 and the outer surrounding portion OSP. In addition, the acute angles between other conductive lines CW and the outer surrounding portion OSP may be different from the acute angle θ1 and the acute angle θ2.

Through the design of the acute angle between the conductive line CW and the outer surrounding portion OSP mentioned above, the coupling between the conductive line CW and the outer surrounding portion OSP may be reduced, thereby improving the reliability of the electronic device ED.

In some embodiments, some of the conductive lines CW may have the same first acute angle with the outer surrounding portion OSP, and some of the conductive lines CW may have the same second acute angle with the outer surrounding portion OSP, wherein the first acute angle may be different from the second acute angle. In other words, the electronic device ED may include multiple groups of conductive lines CW, wherein the acute angles included between the conductive lines CW in the same group and the outer surrounding portion OSP may be the same, and the acute angles between the conductive lines CW in different groups and the outer surrounding portion may be different. For example, as shown in FIG. 4, the conductive line CW3 and the conductive line CW4 may respectively have the acute angle θ3 with the outer surrounding portion OSP, and the conductive line CW5 and the conductive line CW6 may respectively have the acute angle θ4 with the outer surrounding portion OSP, wherein the acute angle θ3 may be different from the acute angle θ4, but not limited thereto. In some embodiments, the conductive lines CW in the same group may be parallel to each other. For example, the conductive line CW3 may be parallel to the conductive line CW4, and the conductive line CW5 may be parallel to the conductive line CW6, but not limited thereto. Through the above-mentioned design, the process difficulty of the conductive lines CW may be reduced under the condition that the acute angles between different conductive the outer surrounding portion OSP are different.

The feature of the acute angle between the conductive line CW and the outer surrounding portion OSP may be applied to the embodiments and variant embodiments of the present disclosure.

According to the present embodiment, the gate driving circuits GC disposed in the peripheral region PR may be partially arranged in an arc shape, but not limited thereto. Specifically, a portion of the transistors in the gate driving circuits GC may be arranged in an arc shape. In detail, as shown in FIG. 4, the disposition region the gate driving circuits GC (or the transistors in the gate driving circuits GC) may include a linear region LR and the curved regions CUR at two sides of the linear region LR. In other words, the linear region LR may be connected between the two curved regions CUR. The transistors in the gate driving circuits GC disposed in the linear region LR may be arranged in a straight line, and transistors in the gate driving circuits GC disposed in the curved region CUR may be arranged in an arc shape. In the present embodiment, the gate driving circuits GC in the curved region CUR may for example be defined through the following way. First, an extending line EXL passing through the outer edge of the gate driving circuit GC disposed in the linear region LR may be defined at first, and then the portion of the gate driving circuits GC which the outer edges thereof are deviated from the extending line EXL may be regarded as the gate driving circuits GC in the curved region CUR. According to the present embodiment, the transistors in the gate driving circuits GC disposed in the curved region CUR may be arranged along the arc-shaped edge of the outer surrounding portion OSP, but not limited thereto. In such condition, the range of the curved region CUR may be determined according to the position of the arc-shaped edge of the outer surrounding portion OSP. The curved region CUR may be closer to the corner COR of the substrate SB than the linear region LR. In other words, the portion of the transistors in the gate driving circuits GC close to the corner COR of the substrate SB may be arranged in an arc shape. It should be noted that although it is not mentioned above, FIG. 2 also shows the design that the gate driving circuits GC may be arranged along the arc-shaped edge of the outer surrounding portion OSP. In addition, in the present embodiment, as shown in FIG. 4, in the gate driving circuits GC, a distance D3 may be included between two adjacent transistors disposed in the linear region LR, and a distance D4 may be included between two adjacent transistors disposed in the curved region CUR, wherein the distance D3 and the distance D4 may be different. For example, the distance D3 may be less than the distance D4, but not limited thereto. The distance D3 may be defined as the minimum distance between two adjacent transistors in the linear region LR, and the distance D4 may be defined as the minimum distance between two adjacent transistors in the curved region CUR, but not limited thereto. In other words, the density of the transistors in the gate driving circuits GC may be greater in the linear region LR than in the curved region CUR. Through the arrangement design and the distance design of the gate driving circuits GC mentioned above, the spatial configuration of the electronic device ED may be improved. The arrangement design and the distance design of the gate driving circuits GC described herein may be applied to the embodiments and variant embodiments of the present disclosure.

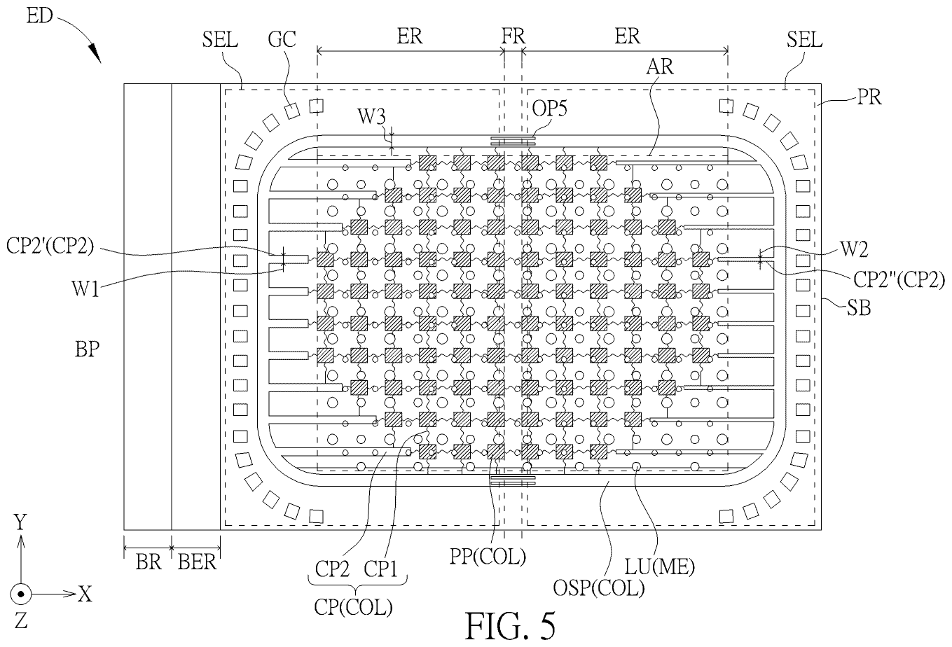

Referring to FIG. 5, FIG. 5 schematically illustrates a top view of an electronic device according to a third embodiment of the present disclosure. In the present embodiment, as mentioned above, the sensing layer SEL may not be disposed corresponding to the foldable sub region FR in the active region AR. Specifically, the electronic device ED may include two sensing layers SEL respectively disposed at two sides of the foldable sub region FR, but not limited thereto. In such condition, in the top view of the electronic device ED, a portion of the outer surrounding portion OSP may overlap the sensing layer SEL, and another portion of the outer surrounding portion OSP may be located outside the sensing layer SEL or not overlap the sensing layer SEL. Specifically, the portion of the outer surrounding portion OSP corresponding to the foldable sub region FR may be located outside the sensing layer SEL.

In the present embodiment, the conductive layer COL may cross the foldable sub region FR, or a portion of the conductive layer COL may be disposed corresponding to the foldable sub region FR. Specifically, the outer surrounding portion OSP of the conductive layer COL may partially correspond to the foldable sub region FR. For example, as shown in FIG. 5, the outer surrounding portion OSP may extend in the flat sub regions ER and cross the foldable sub region FR, but not limited thereto. The connecting portion CP of the conductive layer COL may cross the foldable sub: region FR. Specifically, as shown in FIG. 5, the connecting portion CP1 connected between the pattern portions PP respectively at two sides of the foldable sub region FR may cross the foldable sub region FR. In other words, the conductive layer COL may include a pattern portion PP overlapped with a first transistor (that is, the transistor in the driving circuit DU) at a side of the foldable sub region FR, another pattern portion PP overlapped with another first transistor (that is, the transistor in the driving circuit DU) at another side of the foldable sub region FR and a connecting portion CP1 connecting the pattern portion PP and the another pattern portion PP, wherein the connecting portion CP1 may cross the foldable sub region FR. In some embodiments, the connecting portion CP2 connecting the pattern portion PP and the outer surrounding portion OSP may overlap the foldable sub region FR. In some embodiments, the pattern portion PP may overlap the foldable sub region FR.

According to the present embodiment, the portion of the conductive layer COL corresponding to the foldable sub region FR may include opening. In detail, as shown in FIG. 5, the portion of the outer surrounding portion OSP of the conductive layer COL corresponding to the foldable sub region FR may include at least one opening OP5, or the outer surrounding portion OSP includes the opening OP5 that crosses the foldable sub region FR. Through the above-mentioned design, the flexibility of the conductive layer COL may be improved. It should be noted that although it is not shown in FIG. 5, in the top view of the electronic device ED, the connecting portion CP of the conductive layer COL that is partially overlapped with the foldable sub region FR may include at least one opening in the foldable sub region FR, or the connecting portion CP may include the opening corresponding to the foldable sub region FR. In some embodiments, the pattern portion PP overlapped with the foldable sub region FR may include the opening corresponding to the foldable sub region FR.

According to the present embodiment, the thickness of the portion of the conductive layer COL outside the foldable sub region FR and the thickness of the portion of the conductive layer COL in the foldable sub region FR may be different. “The portion of the conductive layer COL outside the foldable sub region FR” mentioned above may for example include the portion of the conductive layer COL in the flat sub region ER. Specifically, the thickness of the portion of the conductive layer COL in the flat sub region ER may be greater than the thickness of the portion of the conductive layer COL in the foldable sub region FR. For example, although it is not shown in FIG. 5, the thickness of the portion of the outer surrounding portion OSP in the flat sub region ER may be greater than the thickness of the portion of the outer surrounding portion OSP in the foldable sub region FR. In addition, the thickness of the portion of the connecting portion CP (which is overlapped with the foldable sub region FR) in the flat sub region ER may be greater than the thickness of the portion of the connecting portion CP in the foldable sub region FR. In the present embodiment, a ratio of the thickness of the portion of the conductive layer COL in the flat sub region ER to the thickness of the portion of the conductive layer COL in the foldable sub region FR may range from 1.1 to 2 (that is, 1.1≤ratio≤2), but not limited thereto. In some embodiments, the above-mentioned ratio may range from 1.2 to 1.9 (that is, 1.2≤ratio≤1.9). In some embodiments, the above-mentioned ratio may range from 1.3 to 1.8 (that is, 1. 3≤ratio≤1.8). The above-mentioned design that the conductive layer COL includes different thicknesses in different regions may for example be achieved by forming recesses in the portion of the conductive layer COL corresponding to the foldable sub region FR, but not limited thereto. The thickness design of the conductive layer COL mentioned above may reduce the possibility of breakage of the conductive layer COL when the electronic device ED is folded, thereby improving the flexibility of the conductive layer COL. The designs of opening and thickness of the conductive layer COL mentioned above may be applied to the embodiments and variant embodiments of the present disclosure.

According to the present embodiment, in the top view of the electronic device ED, the disposition range of the conductive layer COL may substantially correspond to the disposition range of the sensing layer SEL. The disposition range of the conductive layer COL may for example be the range enclosed by the outer surrounding portion OSP. The disposition range of the sensing layer SEL may for example be the range enclosed by the outer edge of the sensing layer SEL. Specifically, in the top view of the electronic device ED, a ratio of the area of the portion of the disposition range of the sensing layer SEL overlapped with the disposition range of the conductive layer COL to the area of the disposition range of the sensing layer SEL may be greater than or equal to 0.8, but not limited thereto. In other words, the area of the portion of the disposition range of the sensing layer SEL occupied by the disposition range of the conductive layer COL may be at least 80% of the area of the disposition range of the sensing layer SEL. In some embodiments, the disposition range of the conductive layer COL may be smaller than the disposition range of the sensing layer SEL, for example, the disposition range of the conductive layer COL may be located in the disposition range of the sensing layer SEL, but not limited thereto. Through the above-mentioned design, the possibility of electrostatic discharge caused by the sensing layer SEL may be reduced through the conductive layer COL.

According to the present embodiment, in the conductive layer COL, the width of the outer surrounding portion OSP may be greater than the width of the connecting portion CP connected between the pattern portion PP and the outer surrounding portion OSP (that is, the connecting portion CP2), but not limited thereto. For example, as shown in FIG. 5, the outer surrounding portion OSP may have a width W3, wherein the width W3 may be greater than the width (that is, the width W1 and the width W2 mentioned above) of the connecting portion CP2 connected between the pattern portion PP and the outer surrounding portion OSP. In other words, the width W3 may be greater than the width W1, and the width W1 may be greater than the width W2. It should be noted that the width W3 may be greater than the widths of other connecting portions CP2 connected between the pattern portions PP and the outer surrounding portion OSP, which is not limited to the width mentioned above. In some embodiments, the width W3 of the outer surrounding portion OSP may be greater than the width of the connecting portion CP1 connected between the pattern portions PP. Through the width design mentioned above, the anti-electrostatic discharge effect of the conductive layer COL may be improved.

Referring to FIG. 6, FIG. 6 schematically illustrates a partial top view of an electronic device according to a fourth embodiment of the present disclosure. FIG. 6 shows the top view of a portion of the electronic device ED adjacent to outer surrounding portion OSP of the conductive layer COL. In addition, the pattern design of the conductive layer COL shown in FIG. 6 may be different from the pattern design of the conductive layers COL in the above-mentioned embodiments, and the patterns of the conductive layers COL in the embodiments may be applied to each other. According to the present embodiment, as shown in FIG. 6, the electronic device ED may include a transistor T3 disposed in the active region AR and adjacent to the outer surrounding portion OSP of the conductive layer COL and a transistor T2 disposed in the peripheral region PR and adjacent to the outer surrounding portion OSP of the conductive layer COL, wherein the transistor T3 may be electrically connected to transistor T2 (for example, through the conductive line CW). The above-mentioned T3 may be the transistor in the driving circuit DU, and the transistor T2 may be the transistor in the gate driving circuit GC that is electrically connected to the transistor T3. It should be noted that in order to simplify the figure, the detail of electrical connection between some of the transistors in the gate driving circuits GC and some of the transistors in the driving circuits DU is omitted in FIG. 6. In the present embodiment, “the transistor T3 is adjacent to the outer surrounding portion OSP” may indicate that no other transistor in the driving circuit DU is included between the transistor T3 and the outer surrounding portion OSP. Similarly, “the transistor T2 is adjacent to the outer surrounding portion OSP” may indicate that no other transistor in the gate driving circuit GC is included between the transistor T2 and the outer surrounding portion OSP. For example, the transistor T3 may be the transistor among the transistors in one of the plurality of driving circuits DU adjacent to the outer surrounding portion OSP that is closest to the outer surrounding portion OSP, and the transistor T2 in the gate driving circuit GC may be electrically connected to the transistor T3 and adjacent to the outer surrounding portion OSP. According to the present embodiment, a first distance B1 is included between the outer surrounding portion OSP and the transistor T3, and a second distance B2 may be included between the outer surrounding portion OSP and the transistor T2, wherein a ratio of the second distance B2 to the first distance B1 may be greater than or equal to 0.8 and less than or equal to 10 (that is, 0.8≤B2/B1≤10). The first distance B1 mentioned above may be defined as the minimum distance between the outer surrounding portion OSP and the channel region (such as the above-mentioned channel region CR) of the transistor T3, and the above-mentioned second distance B2 may be defined as the minimum distance between the outer surrounding portion OSP and the channel region of the transistor T2. For example, the first distance B1 may be the distance between the outer surrounding portion OSP and the channel region of the transistor T3 in the direction X, and the second distance B2 may be the distance between the outer surrounding portion OSP and the channel region of the transistor T2 in the same direction X, but not limited thereto. In some embodiments, the ratio of the second distance B2 to the first distance B1 may be greater than 1 and less than or equal to 5 (that is, 1<B2/B1≤5). In such condition, the first distance B1 may be less than the second distance B2, that is, the outer surrounding portion OSP may be closer to the driving circuits DU than the gate driving circuits GC. In other words, the above-mentioned ratio may be used to describe the relationship between the distances respectively between two transistors which are electrically connected to each other and located at two sides of the outer surrounding portion OSP and the outer surrounding portion OSP. In some embodiments, the above-mentioned ratio may be used to describe the relationship between the distance between a transistor in the driving circuit DU adjacent to the outer surrounding portion OSP and the outer surrounding portion OSP and the distance between another transistor in the gate driving circuit GC adjacent to the outer surrounding part OSP and the outer surrounding portion OSP, wherein the transistor may not be electrically connected to the another transistor. Through the above-mentioned distance design, the anti-electrostatic discharge effect of the conductive layer COL may be improved. In summary, in the present embodiment, the electronic device ED may include a first transistor (that is, the above-mentioned transistor T3) disposed in the active region AR and a second transistor (that is, the above-mentioned transistor T2) disposed in the peripheral region PR and electrically connected to the first transistor, wherein the first transistor and the second transistor are disposed adjacent to the outer surrounding portion OSP, and a ratio of the second distance between the outer surrounding portion OSP and the second transistor to the first distance between the outer surrounding portion OSP and the first transistor may be located within the above-mentioned range. It should be noted that the above-mentioned ratio of the distances may be applied to another first transistor adjacent to the outer surrounding portion OSP and another second transistor adjacent to the outer surrounding portion OSP and electrically connected to the another first transistor in the electronic device ED, which is not limited to the transistor T2 and the transistor T3 shown in FIG. 6. The ratio of the distances mentioned above may be applied to the embodiments and variant embodiments of the present disclosure.

In addition, in the present embodiment, the transistors in the gate driving circuits GC may be arranged in multiple columns in the peripheral region PR. For example, as shown in FIG. 6, the transistors in the gate driving circuits GC may be disposed in the peripheral region PR in two columns, but not limited thereto. In the present embodiment, a pitch PT1 may be included between the transistors in a column of gate driving circuits GC, and a pitch PT2 may be included between the transistors in another column of gate driving circuits GC, wherein the pitch PT1 may be different from the pitch PT2, but not limited thereto.

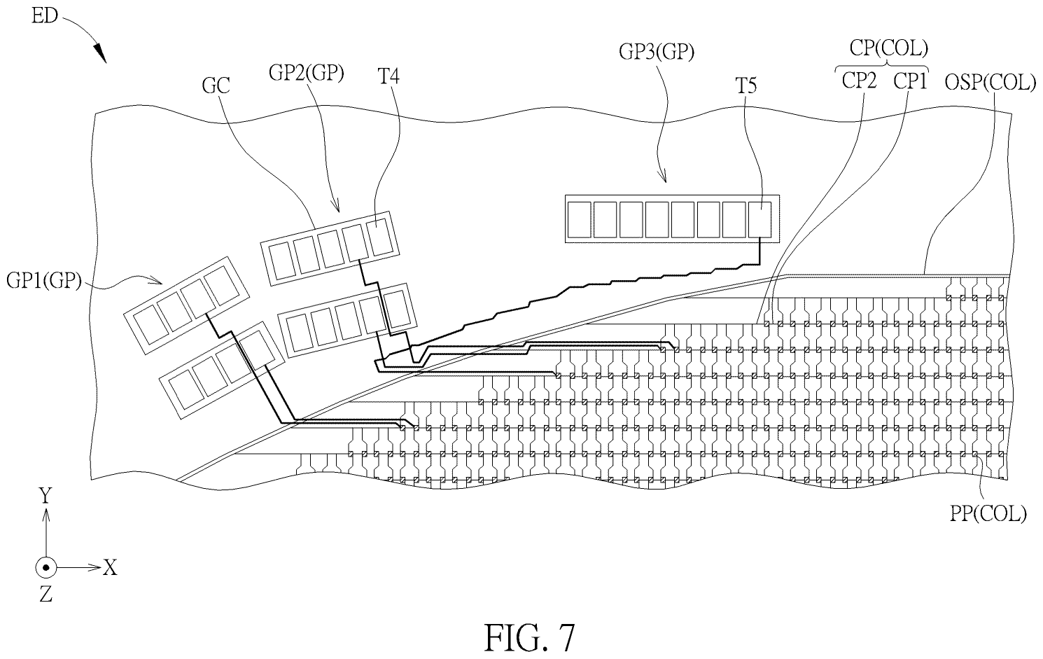

Referring to FIG. 7, FIG. 7 schematically illustrates a partial top view of an electronic device according to a fifth embodiment of the present disclosure. Specifically, FIG. 7 shows the top view of a portion of the electronic device ED adjacent to the arc-shaped edge of the outer surrounding portion OSP. In the present embodiment, the transistors (for example, the transistor T4) in the gate driving circuits GC disposed in the peripheral region PR and adjacent to the arc-shaped edge of the outer surrounding portion OSP may be divided into a plurality of groups GP, such as the group GP1, the group GP2 and the group GP3, wherein the groups GP may be arranged along the arc-shaped edge of the outer surrounding portion OSP. Specifically, among the transistors in the gate driving circuits GC adjacent to the arc-shaped edge of the outer surrounding portion OSP, the plurality of transistors arranged in the same direction may be regarded as the transistors in the same group GP. In other words, the transistors in each of the groups GP may be arranged in a certain direction, but not limited thereto. In the present embodiment, the frame shown in FIG. 2 for representing the gate driving circuit GC may include at least one transistor. It should be noted that although it is not shown in FIG. 7, the transistors in the gate driving circuits GC disposed in the linear region LR (as shown in FIG. 4) may also be arranged in the above-mentioned way, but not limited thereto. In the present embodiment, the numbers of the transistors in the groups GP may be the same or different, it is not limited in the present embodiment. In the present embodiment, the above-mentioned distance D4 (shown in FIG. 4) between two adjacent transistors disposed in the curved region CUR (shown in FIG. 4) may be the minimum distance between two groups GP, but not limited thereto. In other words, the distance D4 may be the minimum distance between two transistors respectively in two adjacent groups GP that are closest to each other. In some embodiments, the distance D4 may be the minimum distance between two adjacent transistors in the same group GP. It should be noted that the above-mentioned distance D3 may be the minimum distance between two groups GP disposed in the linear region LR in some embodiments. In addition, in the present embodiment, as shown in FIG. 7, the conductive line CW connected between the pattern portion PP and the transistor (such as the transistor T5) in the group GP at an end of the gate driving circuits GC may substantially extend along the arc-shaped edge of the outer surrounding portion OSP at first, and then extending into the active region AR and be electrically connected to the transistor in the driving circuit DU. It should be noted that in order to simplify the figure, FIG. 7 does not show the detail of electrical connection between all of the transistors in the gate driving circuits GC and all of the transistors in the driving circuits DU. Specifically, each of the transistors in the gate driving circuits GC may be electrically connected to at least one conductive line CW, and thereby being electrically connected to a transistor in the driving circuit DU through the at least one conductive line CW. In other words, a group GP shown in FIG. 7 may for example be electrically connected to the conductive lines CW of a number the same as the number of the transistors in the group GP.

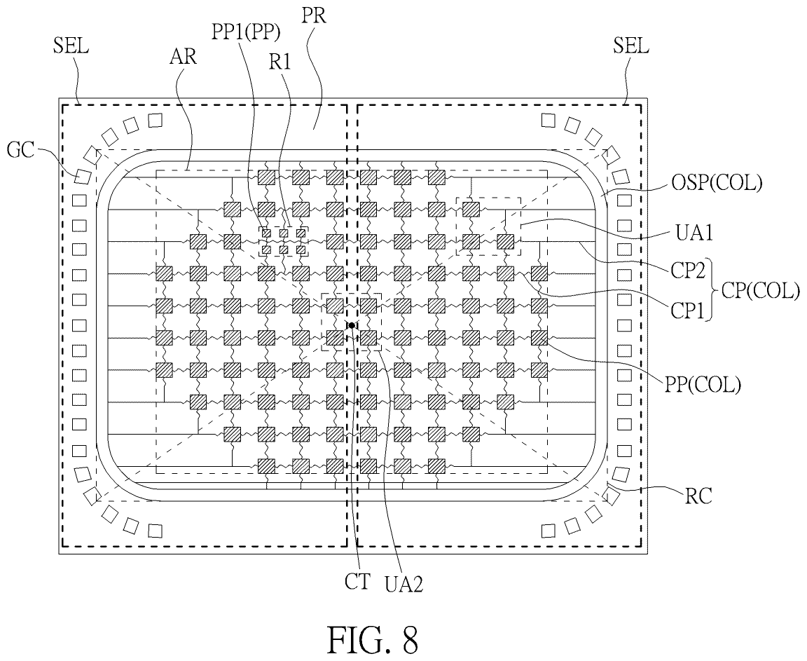

Referring to FIG. 8, FIG. 8 schematically illustrates a top view of an electronic device according to a sixth embodiment of the present disclosure. In order to simplify the figure, FIG. 8 just shows the substrate SB, the sensing layer SEL and the conductive layer COL disposed on the substrate SB, and the features of other elements and layers may refer to the contents in the embodiments mentioned above. The structural feature of the sensing layer SEL of the present embodiment may refer to FIG. 5 and related contents above. According to the present embodiment, the sizes of the pattern portions PP of the conductive layer COL may be different in different regions. For example, as shown in FIG. 8, the pattern portions PP (for example, the pattern portion PP1) disposed in a region R1 may have a smaller size than other pattern portions PP, but not limited thereto. “The size of the pattern portion PP” mentioned above may be the width, the length or the area of the pattern portion PP, but not limited thereto. It should be noted that the size and the position of the region R1 shown in FIG. 8 are exemplary, and the present embodiment is not limited thereto. Specifically, the size and the position of the region R1 may be determined based on certain electronic element of the electronic device ED. In the present embodiment, the region R1 may correspond to the disposition region of the sensing element of the electronic device ED, but not limited thereto. The sensing element may include an optical sensing element or other suitable sensing elements. For example, the region R1 may correspond to the disposition region of the optical sensing element (such as camera, but not limited thereto) of the electronic device ED, but not limited thereto. The optical sensing element may include any suitable element capable of sensing visible light or infrared light, but not limited thereto. In other words, the size of the pattern portions PP corresponding to the disposition region of the optical element may be smaller than the size of other pattern portions PP. In some embodiments, the region R1 may correspond to the disposition region of any suitable element of the electronic device ED. Through the above-mentioned design, the influence of the pattern portions PP of the conductive layer COL on the electronic elements of the electronic device ED may be reduced, thereby improving the performance of the electronic device ED. In some embodiments, the pattern portions PP in the region R1 may have a greater size than other pattern portions PP. In some embodiments, the shape of the pattern portions PP in region R1 may be different from the shape of other pattern portions PP.

In addition, in the present embodiment, the pattern portions PP disposed in the active region AR may have different densities in different regions. Specifically, the density of the pattern portions PP away from the peripheral region PR (or away from the outer surrounding portion OSP) may be greater than the density of the pattern portions PP closer to the outer surrounding portion OSP. In detail, as shown in FIG. 8, a portion of the pattern portions PP in a first unit area UA1 may have a first density, another portion of the pattern portions PP in a second unit area UA2 may have a second density, and the first unit area UA1 is closer to the peripheral region PR than the second unit area UA2, wherein the first density is less than the second density. “The first unit area UA1 is closer to the peripheral region PR than the second unit area UA2” mentioned above may represent that the minimum distance between the first unit area UA1 and the peripheral region PR is less than the minimum distance between the second unit area UA2 and the peripheral region PR, but not limited thereto. The first unit area UA1 and the second unit area UA2 may have any suitable size, such as 30 μm*30 μm, 50 μm*50 μm or 1 millimeter (mm)*1 mm, but not limited thereto. The above-mentioned first density may be defined as the ratio of the sum of the areas of the pattern portions PP in the first unit area UA1 to the first unit area UA1, that is, the proportion of the area of the pattern portions PP in the first unit area UA1. The second density may be defined in the same way, and will not be redundantly described. In the present embodiment, the pattern portions PP having different densities in different regions may for example be achieved by making the pattern portion PP not disposed at certain position, but not limited thereto. Specifically, the density of the pattern portions PP in the first unit area UA1 may be lower by not disposing the pattern portion PP at the position adjacent to the arc-shaped edge of the outer surrounding portion OSP. For example, in the present embodiment, in the top view of the electronic device ED, the portion of the pattern portions PP adjacent to the peripheral region PR may be in a stepped arrangement, but not limited thereto.

It should be noted that the shapes and positions of the first unit area UA1 and the second unit area UA2 mentioned above are exemplary, and the present disclosure is not limited thereto. In the present embodiment, the second unit area UA2 may be defined as the unit area with any suitable size or shape that is located in the central region of the conductive layer COL, and the first unit area UA1 may be defined as the unit area with any suitable size or shape that is located in the edge region of the conductive layer COL. In other words, the density of the pattern portions PP disposed in the central region of the conductive layer COL may be greater than the density of the pattern portions PP disposed in the edge region of the conductive layer COL. Specifically, a minimum rectangle RC enclosing the conductive layer COL may be defined at first, for example, the minimum rectangle RC may be the minimum rectangle enclosing the outer surrounding portion OSP of the conductive layer COL. After that, the center point CT at which two diagonals of the minimum rectangle RC intersect may be defined, and an unit area in which the center point CT is included may be the unit area located in the central region of the conductive layer COL, that is, the second unit area UA2; an unit area in which the center point CT is not included may be the unit area located in the edge region of the conductive layer COL, that is, the first unit area UA1. In other embodiments, the first unit area UA1 and the second unit area UA2 may be defined through other suitable ways. In some embodiments, the density of the pattern portion PP may reduce as the distance between the pattern portion PP and the peripheral region PR reduce, which is not limited to the structure shown in FIG. 8. Through the above-mentioned design, the anti-electrostatic discharge effect of the conductive layer COL may be improved. The design of the pattern portions PP mentioned above may be applied to the embodiments and variant embodiments of the present disclosure.

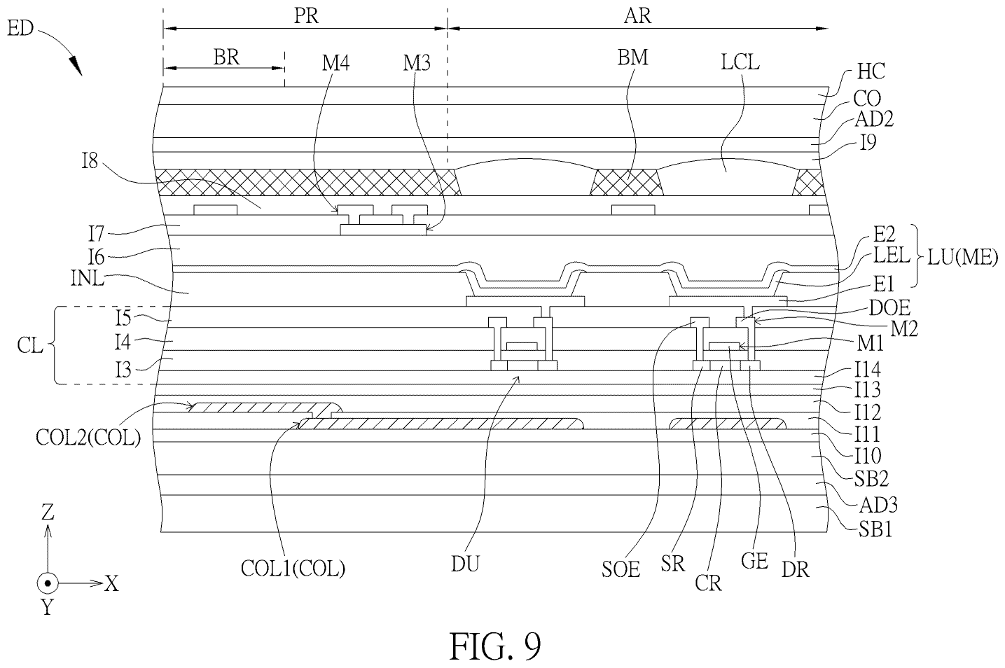

Referring to FIG. 9, FIG. 9 schematically illustrates a partial cross-sectional view of an electronic device according to a seventh embodiment of the present disclosure. In the present embodiment, the electronic device ED may include a dual substrate structure. For example, as shown in FIG. 9, the electronic device ED may include a substrate SB1, a substrate SB2 and an adhesive layer AD3 disposed between the substrate SB1 and the substrate SB2, but not limited thereto. The materials of the substrate SB1 and the substrate SB2 may refer to the material of the substrate SB mentioned above, and will not be redundantly described. Specifically, the substrate SB1 may be attached to the substrate SB2 through the adhesive layer AD3, but not limited thereto. It should be noted that although it is not shown in FIG. 9, the electronic device ED of the present embodiment may further include elements or layers disposed under the substrate SB1, such as the sensing layer SEL, the electronic unit IC1, the electronic unit IC2, and the like, which may refer to the structure shown in FIG. 1A, but not limited thereto.

According to the present embodiment, the conductive layer COL disposed on the substrate SB1 and the substrate SB2 may include a multi-layer structure. For example, as shown in FIG. 9, the conductive layer COL of the present embodiment may include a sub conductive layer COL1 disposed on the substrate SB2 and a sub conductive layer COL2 disposed on the sub conductive layer COL1, but not limited thereto. In detail, the electronic device ED may include an insulating layer I10 disposed on the substrate SB2, the sub conductive layer COL1 disposed on the insulating layer I10, an insulating layer I11 disposed on the sub conductive layer COL1, the sub conductive layer COL2 disposed on the insulating layer I11 and an insulating layer I12 disposed on the sub conductive layer COL2. The sub conductive layer COL2 may be electrically connected to the sub conductive layer COL1 through the via passing through the insulating layer I11. In the present embodiment, the sub conductive layer COL1 may be disposed in the active region AR, and the sub conductive layer COL2 may be disposed in the peripheral region PR, but not limited thereto. In such condition, the conductive layer COL may be transferred from the sub conductive layer COL1 to the sub conductive layer COL2 when it extends to the peripheral region PR in the present embodiment. It should be noted that the conductive layer COL of the present embodiment may include more sub conductive layers which are electrically connected to each other, which is not limited to what is shown in FIG. 9. In the present embodiment, the sub conductive layer COL1 may for example form the pattern portions PP, the connecting portions CP and the outer surrounding portion OSP of the conductive layer COL, and the conductive layer COL may be transferred to the sub conductive layer COL2 at the bonding sub region BR to be electrically connected to an electronic element (such as the electronic unit IC2 mentioned above). In such condition, the sub conductive layer COL2 may for example form the connecting portions CP3 shown in FIG. 2. In some embodiments, the sub conductive layer COL1 may form the pattern portions PP and the connecting portions CP of the conductive layer COL, and the sub conductive layer COL2 may form the outer surrounding portion OSP of the conductive layer COL. In such condition, the connecting portions (that is, the connecting portions CP2) of the conductive layer COL connecting the pattern portions PP and the outer surrounding portion OSP may be transferred from the sub conductive layer COL1 to the sub conductive layer COL2, thereby being electrically connected to the outer surrounding portion OSP in the sub conductive layer COL2. As shown in FIG. 9, the electronic device ED may further include an insulating layer I13 and an insulating layer I14 disposed between the insulating layer I12 and the driving circuits DU, but not limited thereto. The design of the conductive layer COL of the present embodiment may be applied to the embodiments and variant embodiments of the present disclosure.

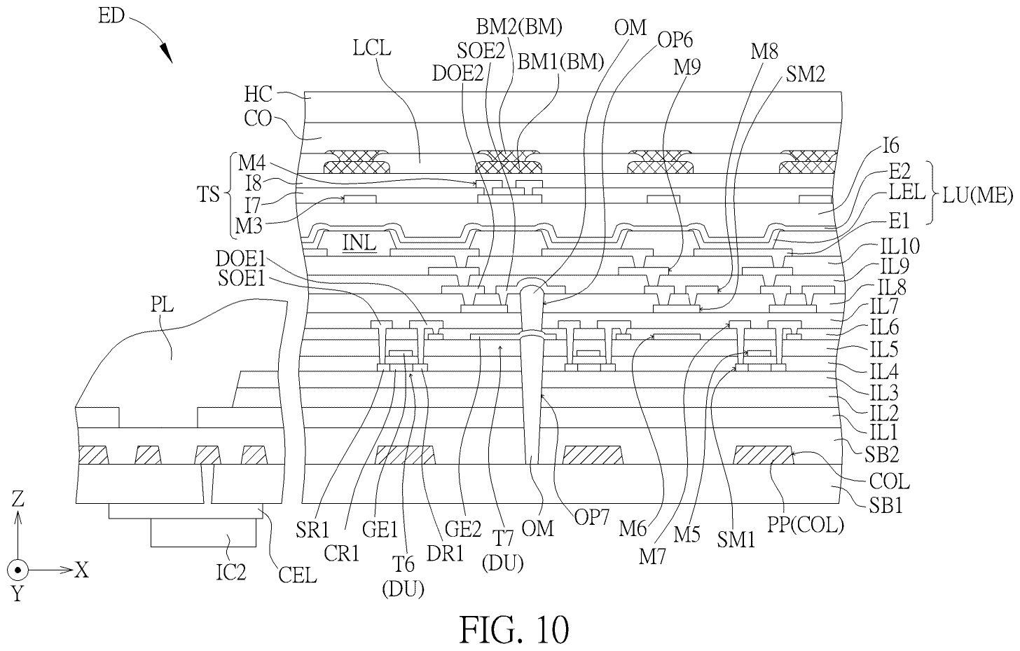

Referring to FIG. 10, FIG. 10 schematically illustrates a cross-sectional view of an electronic device according to an eighth embodiment of the present disclosure. According to the present embodiment, the electronic device ED may include a dual substrate structure. For example, the electronic device ED may for example include the substrate SB1 and the substrate SB2 mentioned above, and the conductive layer COL may be disposed between the substrate SB1 and the substrate SB2, but not limited thereto. In such condition, since the conductive layer COL includes a patterned layer, the substrate SB1 may be connected to the substrate SB2. In some embodiments, the substrate of the electronic device ED may include a multi-layer structure, and the conductive layer COL may be disposed between any two of the layers of the multi-layer structure. The conductive layer COL may for example be electrically connected to other electronic elements (such as the electronic unit IC2, but not limited thereto) through a conductive element CEL passing through the substrate SB1.

In addition, in the present embodiment, a driving circuit DU of the electronic device ED may include a transistor T6 and a transistor T7 disposed on the substrate SB2, wherein the transistor T6 may be electrically connected to the transistor T7, and the transistor T7 may be electrically connected to the electronic element ME (such as the light emitting unit LU). Specifically, the electronic device ED may include a semiconductor layer SM1 disposed on the substrate SB2, an insulating layer IL4 disposed on the semiconductor layer SM1, a conductive layer M5 disposed on the insulating layer IL4, an insulating layer IL5 disposed on the conductive layer M5, a conductive layer M6 disposed on the insulating layer IL5, an insulating layer IL6 disposed on the conductive layer M6, a conductive layer M7 disposed on the insulating layer IL6, an insulating layer IL7 disposed on the conductive layer M7, a semiconductor layer SM2 disposed on the insulating layer IL7, an insulating layer IL8 disposed on the semiconductor layer SM2, a conductive layer M8 disposed on the insulating layer IL8, an insulating layer IL9 disposed on the conductive layer M8, a conductive layer M9 disposed on the insulating layer IL9 and an insulating layer IL10 disposed on the conductive layer M9. The semiconductor SM1 includes the source region SR1, the channel region CR1 and the drain region DR1 of the transistor T6, the conductive layer M5 forms the gate electrode GE1 of the transistor T6, and the conductive layer M7 forms the source electrode SOE1 and the drain electrode DOE1 of the transistor T6 respectively be electrically connected to the source region SR1 and the drain region DR1. The transistor T7 may include the semiconductor layer SM2, the conductive layer M6 forms the gate electrode GE2 of the transistor T7, the conductive layer M8 forms the source electrode SOE2 and the drain electrode DOE2 electrically connected to the semiconductor layer SM2 of the transistor T7. The drain electrode DOE1 of the transistor T6 may be electrically connected to the conductive layer M6 or electrically connected to the gate electrode GE2 of the transistor T7. The electrode E1 of the electronic element ME may be electrically connected to the conductive layer M9, and thereby being electrically connected to the conductive layer M8 through the conductive layer M9. For example, the electrode E1 may be electrically connected to the drain electrode DOE2 of the transistor T7. In other words, the transistor T6 may serve as the switch element, and the transistor T7 may serve as the driving element, but not limited thereto. The semiconductor layer SM1 may include low-temperature polycrystalline silicon (LTPS), and the semiconductor layer SM2 may include metal oxides, such as indium gallium zinc oxide (IGZO), but not limited thereto. In the present embodiment, the pattern portion PP of the conductive layer COL may overlap one of the transistor T6 and the transistor T7. Specifically, the pattern portion PP may overlap the transistor T6 but not overlap the transistor T7, but not limited thereto. It should be noted that the driving circuit DU may further include other transistors, which is not limited to the transistor T6 and the transistor T7 mentioned above.

As shown in FIG. 10, the electronic device ED of the present embodiment may further include an insulating layer IL1, an insulating layer IL2 and an insulating layer IL3 disposed between the transistor T6 and the substrate SB2, but not limited thereto. The insulating layer IL1, the insulating layer IL2 and the insulating layer IL3 for example includes inorganic insulating materials, but not limited thereto.

The features of the electronic elements ME and the touch structure TS of the electronic device ED may refer to FIG. 1B and related contents above, which will not be redundantly described. As shown in FIG. 10, the electronic device ED of the present embodiment may include a black matrix layer BM and optical layers LCL disposed on the touch structure TS, wherein the black matrix layer BM may include a sub black matrix layer BM1 and a sub black matrix layer BM2 disposed on the sub black matrix layer BM1. Specifically, the sub black matrix layer BM1 is disposed on the insulating layer I8 of the touch structure TS and has openings (not labeled), the optical layers LCL are disposed in the openings of the sub black matrix layer BM1, and the sub black matrix layer BM2 is disposed between the optical layers LCL. The electronic device ED may further include a cover layer CO and a hard coating layer HC disposed on the optical layers LCL, but not limited thereto.

According to the present embodiment, the electronic device ED may further include at least one opening penetrating through at least one insulating layer of the electronic device ED. Specifically, the above-mentioned opening may penetrate through at least one inorganic insulating layer of the electronic device ED. For example, as shown in FIG. 10, the electronic device ED may include an opening OP6 and an opening OP7, wherein the opening OP6 may pass through the insulating layer IL6, the insulating layer IL7 and the insulating layer IL8 and expose the conductive layer M6, and the opening OP7 may correspond to the opening OP6, pass through the insulating layer IL5, the insulating layer IL4, the insulating layer IL3, the insulating layer IL2, the insulating layer IL1 and the substrate SB2, and expose the substrate SB1. In such condition, the conductive layer M6 may be located between the opening OP6 and the opening OP7. The electronic device ED may further include an organic material OM filled in the opening OP6 and the opening OP7. In other words, portions of the above-mentioned insulating layers may be removed to form the opening OP6 and the opening OP7 at first, and then the organic material OM may be filled in the opening OP6 and the opening OP7. In the present embodiment, the opening OP6 and the opening OP7 may not be disposed corresponding to the conductive layer COL, and the opening OP7 may extend to be located between the conductive layer COL. “The opening OP7 extends to be located between the conductive layer COL” mentioned above may indicate that the opening OP7 at least extends to a surface on which the conductive layer COL is disposed, such as the surface of the substrate SB1. Specifically, the opening OP7 may at least penetrate through the substrate SB2 and be located between the pattern portions PP of the conductive layer COL. It should be noted that in the present embodiment, the structure of the opening that penetrates through the insulating layer(s) is not limited to what is shown in FIG. 10. In some embodiments, the conductive layer COL may be disposed at any suitable position, and the electronic device ED may at least include an opening extending to be located between the conductive layer COL, wherein the opening may be formed by removing a portion of at least one inorganic insulating layer, and the organic material OM may be filled in the opening. Through the above-mentioned design, the possibility of breakage of the elements and the layers (such as the conductive layer COL, the transistor T6, the transistor T7, and the like) of the electronic device ED may be reduced, thereby improving the reliability of the electronic device ED. The feature described in the present embodiment that the electronic device ED includes the opening at least extending to be located between the conductive layer COL may be applied to the embodiments and variant embodiments mentioned above.

In summary, an electronic device is provided by the present disclosure. The electronic device includes a substrate, a conductive layer disposed on the substrate and transistors in driving circuits disposed on the conductive layer and located in an active region, wherein the conductive layer may reduce the possibility that the transistors in the driving circuits are damaged by electrostatic discharge, thereby improving the reliability of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device having an active region and a peripheral region adjacent to the active region, comprising:
a substrate;
a conductive layer disposed on the substrate;
a first transistor disposed on the conductive layer and in the active region;
a second transistor disposed on the substrate and in the peripheral region; and
a conductive line electrically connected between the first transistor and the second transistor;
wherein in a top view of the electronic device, the conductive layer comprises an outer surrounding portion in the peripheral region and between the first transistor and the second transistor, and the conductive line crosses the outer surrounding portion and is electrically insulated from the outer surrounding portion.

2. The electronic device according to claim 1, wherein the first transistor and the second transistor are disposed adjacent to the outer surrounding portion, a first distance is between the outer surrounding portion and the first transistor, a second distance is between the outer surrounding portion and the second transistor, and a ratio of the second distance to the first distance is greater than or equal to 0.8 and less than or equal to 10.

3. The electronic device according to claim 2, wherein the first distance is less than the second distance.

4. The electronic device according to claim 1, wherein in the top view of the electronic device, an acute angle between the conductive line and the outer surrounding portion is greater than 20 degrees.

5. The electronic device according to claim 1, further comprising another first transistor disposed in the active region, another second transistor disposed in the peripheral region, and another conductive line electrically connected between the another first transistor and the another second transistor, wherein the another conductive line crosses the outer surrounding portion, an acute angle between the conductive line and the outer surrounding portion is different from another acute angle between the another conductive line and the outer surrounding portion.

6. The electronic device according to claim 1, wherein the first transistor is included in a driving circuit and configured to drive an electronic unit in the active region, and the second transistor is included in a gate driving circuit.

7. The electronic device according to claim 1, wherein the electronic device comprises a plurality of the second transistors disposed in the peripheral region, and the plurality of the second transistors are arranged along an arc edge of the outer surrounding portion.

8. The electronic device according to claim 1, wherein the conductive layer comprises a pattern portion overlapped with the first transistor and a connecting portion connecting the pattern portion and the outer surrounding portion, and a width of the outer surrounding portion is greater than a width of the connecting portion.

9. The electronic device according to claim 1, wherein the peripheral region comprises a bonding sub region, the conductive layer comprises a first connecting portion connected to a portion of the outer surrounding portion adjacent to the bonding sub region and a second connecting portion connected to another portion of the outer surrounding portion opposite to the first connecting portion, and a width of the first connecting portion is greater than a width of the second connecting portion.

10. The electronic device according to claim 1, wherein the peripheral region comprises a bonding sub region, the conductive layer comprises a connecting portion connected to a portion of the outer surrounding portion adjacent to the bonding sub region, and the connecting portion is configured to transmit a signal.

11. The electronic device according to claim 1, wherein the electronic device comprises a plurality of the first transistors disposed on the conductive layer and in the active region, and the conductive layer comprises a plurality of pattern portions overlapped with the plurality of the first transistors respectively.

12. The electronic device according to claim 11, wherein a portion of the plurality of pattern portions in a first unit area has a first density, another portion of the plurality of pattern portions in a second unit area has a second density, the first unit area is closer to the peripheral region than the second unit area, and the first density is less than the second density.

13. The electronic device according to claim 11, wherein in the top view of the electronic device, a portion of the plurality of pattern portions adjacent to the peripheral region are in a stepped arrangement.

14. The electronic device according to claim 1, wherein the active region comprises a foldable sub region, the conductive layer comprises a pattern portion overlapped with the first transistor, another pattern portion overlapped with another first transistor and a connecting portion connecting the pattern portion and the another pattern portion, wherein in the top view of the electronic device, the connecting portion crosses the foldable sub region.

15. The electronic device according to claim 14, wherein the active region comprises a flat sub region adjacent to the foldable sub region, a thickness of the connecting portion in the foldable sub region is less than a thickness of the connecting portion in the flat sub region.

16. The electronic device according to claim 14, wherein in the top view of the electronic device, the connecting portion comprises at least one opening in the foldable sub region.

17. The electronic device according to claim 1, further comprising a sensing layer disposed under the substrate, wherein in a normal direction of the electronic device, a third distance is between the conductive layer and the first transistor, a fourth distance is between the conductive layer and the sensing layer, and the third distance is less than the fourth distance.

18. The electronic device according to claim 17, wherein a ratio of the fourth distance to the third distance is greater than or equal to 20 and less than or equal to 1000.

19. The electronic device according to claim 1, further comprising a sensing layer disposed under the substrate, wherein in the top view of the electronic device, a portion of the outer surrounding portion is overlapped with the sensing layer, and another portion of the outer surrounding portion is outside the sensing layer.
